(19) United States
(12) Patent Application Publication
(10) Pub. No.: US 2026/0255651 A1
(43) Pub. Date: Aug. 27, 2026

(54) SEMICONDUCTOR DEVICE

(71) Applicant: Samsung Electronics Co., Ltd., Suwon-si (KR)

(72) Inventors: Gwan Ho Kim, Suwon-si (KR); Ki-Il Kim, Suwon-si (KR); Hyung Goo Lee, Suwon-si (KR); Sung Woo Kang, Suwon-si (KR); Kyong Beom Koh, Suwon-si (KR)

(21) Appl. No.: 19/355,658

(22) Filed: Oct. 10, 2025

(30) Foreign Application Priority Data
Feb. 18, 2025 (KR) 10-2025-0020548

(51) Int. Cl. H10D 64/23; H10D 30/00; H10D 30/01

(52) U.S. Cl. CPC H10D 64/254; H10D 30/0198; H10D 30/501

(57) ABSTRACT

A semiconductor device includes an active pattern, a plurality of nanosheets stacked and spaced apart from each other on the active pattern, a gate electrode on the active pattern, the gate electrode surrounding the plurality of nanosheets, a source/drain region on one side of the gate electrode on the active pattern, a source/drain contact beneath the source/drain region, the source/drain contact extending through the active pattern, the source/drain contact electrically connected to the source/drain region, an isolation trench beneath the plurality of nanosheets, the isolation trench extending through the active pattern, an air gap inside the isolation trench, the air gap overlapping with the gate electrode, and a liner layer along a sidewall and an upper surface of the isolation trench, at least a portion of the liner layer between the air gap and the gate electrode.

### CROSS-REFERENCE TO RELATED APPLICATION

This application claims priority from Korean Patent Application No. 10-2025-0020548 filed on February 18, 2025 in the Korean Intellectual Property Office, and all the benefits accruing therefrom under 35 U.S.C. 119, the contents of which in its entirety are herein incorporated by reference.

### BACKGROUND

The present disclosure relates to a semiconductor device. More particularly, the present disclosure relates to a semiconductor device including a MBCFET^{TM} (Multi-Bridge Channel Field Effect Transistor).

As one of the scaling techniques to increase the density of integrated circuit devices, multi-gate transistors have been proposed, in which a fin-shaped or nanowire-shaped silicon body is formed on a substrate, and gates are formed on the surface of the silicon body.

Since these multi-gate transistors utilize a three-dimensional channel, scaling becomes more feasible. Additionally, the current control capability may be improved without increasing the gate length of the multi-gate transistor. Furthermore, the SCE (short channel effect), in which the potential of the channel region is influenced by the drain voltage, may be effectively suppressed.

### SUMMARY

The present disclosure aims to provide a semiconductor device that improves reliability by reducing the capacitance between adjacent source/drain contacts.

The aspects of the present disclosure are not limited to those mentioned above, and another aspect which is not mentioned may be clearly understood by those skilled in the art from the description below.

According to some implementations of the present disclosure, there is provided a semiconductor device, comprising an active pattern extending in a first horizontal direction, a plurality of nanosheets stacked and spaced apart from each other in a vertical direction on the active pattern, a gate electrode extending in a second horizontal direction different from the first horizontal direction on the active pattern, the gate electrode surrounding the plurality of nanosheets, a source/drain region disposed on one side of the gate electrode on the active pattern, a source/drain contact disposed beneath the source/drain region, the source/drain contact extending through the active pattern in the vertical direction, the source/drain contact electrically connected to the source/drain region, an isolation trench formed beneath the plurality of nanosheets, the isolation trench extending through the active pattern in the vertical direction, an air gap formed inside the isolation trench, the air gap overlapping with the gate electrode in the vertical direction, and a liner layer disposed along a sidewall and an upper surface of the isolation trench, at least a portion of the liner layer disposed between the air gap and the gate electrode.

According to some implementations of the present disclosure, there is provided a semiconductor device, comprising an active pattern extending in a first horizontal direction, a gate electrode extending in a second horizontal direction different from the first horizontal direction on the active pattern, a first source/drain region disposed on a first side of the gate electrode on the active pattern, a second source/drain region disposed on a second side of the gate electrode, opposite to the first side of the gate electrode in the first horizontal direction, on the active pattern, a first source/drain contact disposed beneath the first source/drain region, the first source/drain contact extending through the active pattern in a vertical direction, the first source/drain contact electrically connected to the first source/drain region, a second source/drain contact disposed beneath the second source/drain region, the second source/drain contact extending through the active pattern in the vertical direction, the second source/drain contact electrically connected to the second source/drain region, and an air gap formed between the first and second source/drain contacts, the air gap overlapping with the gate electrode in the vertical direction, wherein a width of the air gap in the second horizontal direction is greater than a width of the first source/drain contact in the second horizontal direction.

According to some implementations of the present disclosure, there is provided a semiconductor device, comprising an insulating pattern, an active pattern extending in a first horizontal direction on an upper surface of the insulating pattern, the active pattern including silicon (Si), a plurality of nanosheets stacked and spaced apart from each other in a vertical direction on the active pattern, a gate electrode extending in a second horizontal direction different from the first horizontal direction on the active pattern, the gate electrode surrounding the plurality of nanosheets, a first source/drain region disposed on a first side of the gate electrode on the active pattern, a second source/drain region disposed on a second side of the gate electrode, opposite to the first side of the gate electrode in the first horizontal direction, on the active pattern, a first source/drain contact disposed beneath the first source/drain region, the first source/drain contact extending through the insulating pattern and the active pattern in the vertical direction, the first source/drain contact electrically connected to the first source/drain region, a second source/drain contact disposed beneath the second source/drain region, the second source/drain contact extending through the insulating pattern and the active pattern in the vertical direction, the second source/drain contact electrically connected to the second source/drain region, an isolation trench formed beneath the plurality of nanosheets, the isolation trench extending through the active pattern in the vertical direction, an air gap formed inside the isolation trench and overlapping with the gate electrode in the vertical direction, and a liner layer disposed along sidewalls and an upper surface of the isolation trench, the liner layer spaced apart from each of the first and second source/drain contacts in the first horizontal direction, at least a portion of the liner layer disposed between the air gap and the gate electrode, wherein at least a portion of the active pattern is disposed between the liner layer and each of the first and second source/drain contacts, and wherein a width of the air gap in the second horizontal direction is greater than a width of the first source/drain contact in the second horizontal direction.

In the diagrams of the semiconductor device according to some of the following implementations, the semiconductor device is described by way of example as including a transistor (MBCFET^{TM} (Multi-Bridge Channel Field Effect Transistor)) that includes a nanosheet. However, this is not intended to limit the present disclosure. In other implementations, the semiconductor device may include a Fin-type transistor (FinFET) having a channel region in the shape of a fin pattern, a tunneling transistor (tunneling FET), or a three-dimensional (3D) structured transistor. Additionally, the semiconductor device according to some other implementations may include a bipolar junction transistor or a lateral double-diffused metal-oxide-semiconductor (LDMOS) transistor.

Hereinafter, the semiconductor device according to some implementations of the present disclosure is described with reference to FIGS. 1 to 4.

FIG. 1 is a layout diagram for explaining a semiconductor device according to some implementations of the present disclosure. FIG. 2 is a cross-sectional view taken along line A-A' in FIG. 1. FIG. 3 is a cross-sectional view taken along line B-B' in FIG. 1. FIG. 4 is a cross-sectional view taken along line C-C' in FIG. 1.

Referring to FIG. 1 to FIG. 4, the semiconductor device according to some implementations of the present disclosure includes a lower interlayer insulating layer 100, an insulating pattern 101, an active pattern F1, a field insulating layer 105, a plurality of nanosheets NW, first and second source/drain regions SD1, SD2, a gate electrode G1, a gate spacer 111, a gate insulating layer 112, a capping pattern 113, an isolation trench T1, a liner layer 120, an air gap 130, first and second source/drain contacts 141, 142, a silicide layer SL, a first etching stop layer 150, a first upper interlayer insulating layer 160, a gate contact CB, a second etching stop layer 170, a second upper interlayer insulating layer 180, and a via V1.

For example, the interlayer insulating layer 100 may include at least one of silicon oxide, silicon nitride, silicon oxynitride, and low-k dielectric materials. Low-k dielectric materials may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylCycloTetraSiloxane (OMCTS), HexaMethylDiSiloxane (HMDS), TriMethylSilyl Borate (TMSB), DiAcetoxyDitertiaryButoxySiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica, or combinations thereof, however, this is not intended to limit the scope of the disclosure.

Hereinafter, the first horizontal direction DR1 and the second horizontal direction DR2 may be defined as being parallel to the upper surface of the lower interlayer insulating layer 100. The second horizontal direction DR2 may be defined as a direction different from the first horizontal direction DR1. The vertical direction DR3 may be defined as a direction perpendicular to both the first horizontal direction DR1 and the second horizontal direction DR2. In other words, the vertical direction DR3 may be defined as a direction perpendicular to the upper surface of the lower interlayer insulating layer 100.

The insulating pattern 101 may be disposed on the upper surface of the lower interlayer insulating layer 100. For example, the bottom surface of the insulating pattern 101 may be in contact with the upper surface of the lower interlayer insulating layer 100. The insulating pattern 101 may include an insulating material. For example, the insulating pattern 101 may include a material used as a mask. For example, the insulating pattern 101 may include silicon oxide (SiO₂), silicon nitride (SiN), silicon oxynitride (SiON), silicon oxycarbonitride (SiOCN), or silicon carbonitride (SiCN), but the present disclosure is not limited to these. The active pattern F1 may extend in the first horizontal direction DR1 on the upper surface of the insulating pattern 101. The bottom surface of the active pattern F1 may be in contact with the upper surface of the insulating pattern 101. For example, the active pattern F1 may include silicon (Si). In some other implementations, the active pattern F1 may also include silicon germanium (SiGe).

The field insulating layer 105 may be disposed on the upper surface of the insulating pattern 101. The field insulating layer 105 may surround the sidewall of the active pattern F1. For example, the field insulating layer 105 may be in contact with the sidewall of the active pattern F1 in the second horizontal direction DR2. For example, the field insulating layer 105 may be in contact with the outer sidewall of the liner layer 120 in the second horizontal direction DR2 as described later. For example, the upper surface of the field insulating layer 105 may be lower than the upper surface of the active pattern F1. In other words, at least a portion of the active pattern F1 may protrude in the vertical direction DR3 above the upper surface of the field insulating layer 105. However, the present disclosure is not limited thereto. In some other implementations, the upper surface of the field insulating layer 105 may be formed on the same plane as the upper surface of the active pattern F1. For example, the field insulating layer 105 may include an oxide layer, a nitride layer, an oxynitride layer, or a combination thereof.

A plurality of nanosheets NW may be disposed on the upper surface of the active pattern F1. The plurality of nanosheets NW may be disposed at the intersection of the active pattern F1 and the gate electrode G1. The plurality of nanosheets NW may include a plurality of nanosheets stacked apart from each other in the vertical direction DR3. In FIGS. 2 and 3, it is shown that the plurality of nanosheets NW includes three nanosheets stacked and spaced apart from each other in the vertical direction DR3, but this is for the convenience of explanation and the present disclosure is not limited to this. In some other implementations, the plurality of nanosheets NW may include four or more nanosheets stacked and spaced apart from each other in the vertical direction DR3. For example, the plurality of nanosheets NW may include silicon (Si). In some other implementations, the plurality of nanosheets NW may include silicon germanium (SiGe).

The gate electrode G1 may extend in the second horizontal direction DR2 on the active pattern F1 and the field insulating layer 105. The gate electrode G1 may surround the plurality of nanosheets NW. For example, the gate electrode G1 may contain one or more of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. The gate electrode G1 may contain conductive metal oxides, conductive metal nitrides, or similar materials, and may also contain the oxidized forms of the aforementioned materials.

The gate spacer 111 may extend in the second horizontal direction DR2 along both sidewalls of the gate electrode G1 on the upper surface of the uppermost nanosheet of the plurality of nanosheets and on the upper surface of the field insulating layer 105. For example, the gate spacer 111 may include at least one of silicon nitride (SiN), silicon oxide (SiO₂), silicon oxycarbonitride (SiOCN), silicon boron nitride (SiBN), silicon oxyboron nitride (SiOBN), silicon oxycarbide (SiOC), and combinations thereof. However, the present disclosure is not limited thereto.

The first source/drain region SD1 may be disposed on the first side of the gate electrode G1 on the active pattern F1. The second source/drain region SD2 may be disposed on the second side of the gate electrode G1 opposite to the first side of the gate electrode G1 in the first horizontal direction DR1 on the active pattern F1. The first and second source/drain regions SD1, SD2 may be in contact with both sidewalls of the plurality of nanosheets NW in the first horizontal direction DR1. For example, the upper surface of each of the first and second source/drain regions SD1, SD2 may be formed higher than the upper surface of the uppermost nanosheet of the plurality of nanosheets.

The gate insulating layer 112 may be disposed between the gate electrode G1 and the gate spacer 111. The gate insulating layer 112 may be disposed between the gate electrode G1 and the active pattern F1. The gate insulating layer 112 may be disposed between the gate electrode G1 and the field insulating layer 105. The gate insulating layer 112 may be disposed between the gate electrode G1 and a plurality of nanosheets NW. The gate insulating layer 112 may be disposed between the gate electrode G1 and the first source/drain region SD1. The gate insulating layer 112 may be disposed between the gate electrode G1 and the second source/drain region SD2. The gate insulating layer 112 may be disposed between the gate electrode G1 and a liner layer 120, which will be described later.

The gate insulating layer 112 may include at least one of silicon oxide, silicon oxynitride, silicon nitride, or a high-k dielectric material having a dielectric constant greater than that of silicon oxide. The high-k dielectric material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The semiconductor device according to some other implementations may include an NC (Negative Capacitance) FET using a negative capacitor. For example, the gate insulating layer 112 may include a ferroelectric material layer having ferroelectric properties and a paraelectric material layer having paraelectric properties.

The ferroelectric material layer may exhibit negative capacitance, while the paraelectric material layer may exhibit positive capacitance. For example, when two or more capacitors are connected in series and each of their capacitances has a positive value, the overall capacitance decreases relative to the capacitance of each individual capacitor. On the other hand, if the capacitances of at least one of the two or more capacitors connected in series has a negative value, the overall capacitance may be greater than the absolute value of each individual capacitance while still being positive.

When the ferroelectric material layer with negative capacitance and the paraelectric material layer with positive capacitance are connected in series, the overall capacitance value of the ferroelectric material layer and the paraelectric material layer connected in series may increase. By utilizing the increase in overall capacitance value, the transistor including the ferroelectric material layer may have a subthreshold swing (SS) of less than 60 mV/decade at room temperature.

The ferroelectric material layer may have ferroelectric properties. The ferroelectric material layer may include, for example, at least one of hafnium oxide, hafnium zirconium oxide, barium strontium titanium oxide, barium titanium oxide, and lead zirconium titanium oxide. As another example, hafnium zirconium oxide may be a material in which zirconium (Zr) is doped into hafnium oxide. In another example, hafnium zirconium oxide may be a compound of hafnium (Hf) and zirconium (Zr) combined with oxygen (O).

The ferroelectric material layer may further include a dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). Depending on which ferroelectric material the ferroelectric material layer contains, the type of dopant contained in the ferroelectric material layer may vary.

If the ferroelectric material layer includes hafnium oxide, the dopant included in the ferroelectric material layer may include, for example, at least one of gadolinium (Gd), silicon (Si), zirconium (Zr), aluminum (Al), and yttrium (Y).

If the dopant is aluminum (Al), the ferroelectric material layer may contain about 3 to 8 at% aluminum. (atomic %). Here, the ratio of the dopant may be a ratio of aluminum relative to the sum of hafnium and aluminum.

If the dopant is silicon (Si), the ferroelectric material layer may contain 2 to 10 at% of silicon. If the dopant is yttrium (Y), the ferroelectric material layer may contain 2 to 10 at% of yttrium. If the dopant is gadolinium (Gd), the ferroelectric material layer may contain 1 to 7 at% of gadolinium. If the dopant is zirconium (Zr), the ferroelectric material layer may contain 50 to 80 at% of zirconium.

The paraelectric material layer may have paraelectric properties. The paraelectric material layer may include, for example, at least one or more of silicon oxide and metal oxides with a high-k dielectric constant. The metal oxides contained in the paraelectric material layer may include, for example, at least one of hafnium oxide, zirconium oxide, and aluminum oxide, but is not limited thereto.

The ferroelectric material layer and the paraelectric material layer may include the same material. While the ferroelectric material layer may have ferroelectric properties, the paraelectric material layer may not have ferroelectric properties. For example, if both the ferroelectric material layer and the paraelectric material layer contain hafnium oxide, the crystal structure of the hafnium oxide included in the ferroelectric material layer is different from the crystal structure of the hafnium oxide included in the paraelectric material layer.

The ferroelectric material layer may have a thickness sufficient to exhibit ferroelectric properties. For example, the thickness of the ferroelectric material layer may range from 0.5 to 10 nm, but is not limited thereto. Since the critical thickness for exhibiting ferroelectric properties may vary depending on the ferroelectric material, the thickness of the ferroelectric material layer may also vary depending on the specific ferroelectric material used.

For example, the gate insulating layer 112 may include a single ferroelectric material layer. In another example, the gate insulating layer 112 may include multiple ferroelectric material layers spaced apart from each other. The gate insulating layer 112 may have a stacked structure in which multiple ferroelectric material layers and multiple paraelectric material layers are alternately stacked.

The first etching stop layer 150 may be disposed on the sidewall of the gate spacer 111. The first etching stop layer 150 may be disposed on the upper surface of the field insulating layer 105. The first etching stop layer 150 may be disposed on the upper surface of each of the first and second source/drain regions SD1, SD2. The first etching stop layer 150 may be disposed on the sidewall of each of the first and second source/drain regions SD1, SD2 in the second horizontal direction DR2. For example, the first etching stop layer 150 may be formed in a conformal manner. For example, the first etching stop layer 150 may include at least one of aluminum oxide, aluminum nitride, hafnium oxide, zirconium oxide, silicon oxide, silicon nitride, silicon oxynitride, and low-k dielectric materials.

The capping pattern 113 may extend in the second horizontal direction DR2 on each of the gate spacer 111, the gate insulating layer 112 and the gate electrode G1. For example, the bottom surface of the capping pattern 113 may be in contact with the first etching stop layer 150. However, the present disclosure is not limited thereto. In some other implementations, the sidewall of the capping pattern 113 may be in contact with the first etching stop layer 150. For example, the capping pattern 113 may include at least one of silicon nitride (SiN), silicon oxynitride (SiON), silicon oxide (SiO₂), silicon carbonitride (SiCN), silicon oxycarbonitride (SiOCN), and combinations thereof. However, the present disclosure is not limited thereto.

The first upper interlayer insulating layer 160 may be disposed on the first etching stop layer 150. The first upper interlayer insulating layer 160 may be disposed on the sidewall of the capping pattern 113. The first upper interlayer insulating layer 160 may cover each of the first and second source/drain regions SD1, SD2 on the field insulating layer 105. For example, the upper surface of the first upper interlayer insulating layer 160 may be formed on the same plane as the upper surface of the capping pattern 113. For example, the first upper interlayer insulating layer 160 may include at least one of silicon oxide, silicon nitride, silicon oxynitride, and low-k dielectric materials.

The gate contact CB may pass through the capping pattern 113 in the vertical direction DR3 and be connected to the gate electrode G1. For example, the upper surface of the gate contact CB may be formed on the same plane as the upper surface of the capping pattern 113. However, the present disclosure is not limited thereto. In some other implementations, the upper surface of the gate contact CB may be formed higher than the upper surface of the capping pattern 113. In FIGS. 2 and 3, the gate contact CB is shown to be formed as a single layer, but the present disclosure is not limited thereto. In some other implementations, the gate contact CB may be formed as a multiple layer. The gate contact CB may contain a conductive material.

The first source/drain contact 141 may be disposed beneath the first source/drain region SD1. The first source/drain contact 141 may pass through the active pattern F1 and the insulating pattern 101 in the vertical direction DR3. In other words, the sidewall of the first source/drain contact 141 may be surrounded by the active pattern F1 and the insulating pattern 101. For example, at least a portion of the first source/drain contact 141 may extend into the inside of the first source/drain region SD1. The first source/drain contact 141 may be electrically connected to the first source/drain region SD1.

The second source/drain contact 142 may be disposed beneath the second source/drain region SD2. The second source/drain contact 142 may be spaced apart from the first source/drain contact 141 in the first horizontal direction DR1. The second source/drain contact 142 may pass through the active pattern F1 and insulating pattern 101 in the vertical direction DR3. In other words, the sidewall of the second source/drain contact 142 may be surrounded by the active pattern F1 and the insulating pattern 101. For example, at least a portion of the second source/drain contact 142 may extend into the inside of the second source/drain region SD2. The second source/drain contact 142 may be electrically connected to the second source/drain region SD2.

For example, the bottom surface of each of the first and second source/drain contacts 141, 142 may be formed on the same plane as the bottom surface of the insulating pattern 101. In FIG. 2 and FIG. 4, it is shown that each of the first and second source/drain contacts 141, 142 is formed as a single layer, but the present disclosure is not limited thereto. In some other implementations, each of the first and second source/drain contacts 141, 142 may be formed as multiple layers. Each of the first and second source/drain contacts 141, 142 may include a conductive material. A silicide layer SL may be disposed along the interface between the first source/drain contact 141 and the first source/drain region SD1. Additionally, the silicide layer SL may be disposed along the interface between the second source/drain contact 142 and the second source/drain region SD2. For example, the silicide layer SL may include a metal silicide material.

An isolation trench T1 may be formed between the first source/drain contact 141 and the second source/drain contact 142. The isolation trench T1 may be formed beneath each of the plurality of nanosheets NW and gate electrodes G1. The isolation trench T1 may pass through the active pattern F1 and the field insulating layer 105 and extend in the vertical direction DR3 to the uppermost surface of the active pattern F1. For example, the isolation trench T1 may extend in the second horizontal direction DR2. For example, the isolation trench T1 may be spaced apart from each of the first and second source/drain contacts 141, 142 in the first horizontal direction DR1. For example, the isolation trench T1 may separate the active pattern F1 in the first horizontal direction DR1.

For example, the upper surface of the isolation trench T1 may be defined by the gate insulating layer 112. The sidewalls of the isolation trench T1 in the first horizontal direction DR1 may be defined by an active pattern F1. The sidewalls of the isolation trench T1 in the second horizontal direction DR2 may be defined by the field insulating layer 105. The bottom surface of the isolation trench T1 may be defined by the insulating pattern 101. For example, the bottom surface of the isolation trench T1 may be formed higher than the bottom surface of each of the first and second source/drain contacts 141, 142. For example, at least a portion of the isolation trench T1 may overlap with each of the first and second source/drain regions SD1, SD2 in the first horizontal direction DR1. For example, at least a portion of the isolation trench T1 may overlap with the gate electrode G1 in the second horizontal direction DR2, but the present disclosure is not limited thereto.

For example, the width of the upper surface of the isolation trench T1 in the first horizontal direction DR1 may be smaller than the width of the bottom surface of the isolation trench T1 in the first horizontal direction DR1. The width of the upper surface of the isolation trench T1 in the second horizontal direction DR2 may be smaller than the width of the bottom surface of the isolation trench T1 in the second horizontal direction DR2. The width of the bottom surface of the isolation trench T1 in the second horizontal direction DR2 may be greater than the width of each of the first and second source/drain contacts 141, 142 in the second horizontal direction DR2. The width of the bottom surface of the isolation trench T1 in the second horizontal direction DR2 may be greater than the width of the active pattern F1 in the second horizontal direction DR2.

An air gap 130 may be formed inside the isolation trench T1. In other words, the air gap 130 may be formed between the first source/drain contact 141 and the second source/drain contact 142. The air gap 130 may be formed beneath each of the plurality of nanosheets NW and the gate electrode G1. In other words, the air gap 130 may overlap with each of the plurality of nanosheets NW and the gate electrode G1 in the vertical direction DR3. For example, the air gap 130 may extend in the second horizontal direction DR2. For example, the air gap 130 may be spaced apart from each of the first and second source/drain contacts 141, 142 in the first horizontal direction DR1.

For example, the air gap 130 may be spaced apart from the active pattern F1 in the first horizontal direction DR1. The air gap 130 may be spaced apart from the field insulating layer 105 in the second horizontal direction DR2. For example, the air gap 130 may be spaced apart from the gate insulating layer 112 in the vertical direction DR3. For example, the air gap 130 may be spaced apart from the upper surface of the insulating pattern 101 in the vertical direction DR3. For example, the bottom surface of the air gap 130 may be formed higher than the upper surface of the insulating pattern 101. For example, the width of the air gap 130 in the second horizontal direction DR2 may be greater than the width of each of the first and second source/drain contacts 141, 142 in the second horizontal direction DR2. The width of the air gap 130 in the second horizontal direction DR2 may be greater than the width of the active pattern F1 in the second horizontal direction DR2.

The liner layer 120 may be disposed inside the isolation trench T1. For example, the liner layer 120 may be disposed along the sidewalls and the upper surface of the isolation trench T1. Additionally, the liner layer 120 may be disposed along the bottom surface of the isolation trench T1. The liner layer 120 may surround the surface of the air gap 130. In other words, the air gap 130 may be defined as the space surrounded by the liner layer 120. For example, the outer sidewall of the liner layer 120 in the first horizontal direction DR1 may be spaced apart from each of the first and second source/drain contacts 141, 142 in the first horizontal direction DR1. For example, at least a portion of the active pattern F1 may be disposed between each of the first and second source/drain contacts 141, 142 and the liner layer 120.

For example, the outer sidewall of the liner layer 120 in the first horizontal direction DR1 may be in contact with the active pattern F1. The outer sidewall of the liner layer 120 in the second horizontal direction DR2 may be in contact with the field insulating layer 105. The uppermost surface of the liner layer 120 may be in contact with the gate insulating layer 112. In other words, the gate insulating layer 112 may be disposed between the uppermost surface of the liner layer 120 and the gate electrode G1. For example, the lowermost surface of the liner layer 120 may be in contact with the upper surface of the insulating pattern 101. In other words, the lowermost surface of the liner layer 120 may be formed higher than the bottom surfaces of the first and second source/drain contacts 141, 142, respectively. For example, at least a portion of the liner layer 120 may be disposed between the air gap 130 and the gate electrode G1. In other words, at least a portion of the liner layer 120 may be disposed between the air gap 130 and the gate insulating layer 112.

The liner layer 120 may include insulating materials. For example, the liner layer 120 may contain carbon (C) atoms. For example, the liner layer 120 may include silicon oxycarbide (SiOC), silicon carbide (SiC), silicon carbonitride (SiCN), or silicon oxycarbonitride (SiOCN). In some other implementations, the liner layer 120 may also include silicon nitride (SiN) or silicon oxide (SiO₂).

The second etching stop layer 170 may be disposed on the upper surfaces of the first upper interlayer insulating layer 160, the capping pattern 113, and the gate contact CB, respectively. In FIGS. 2 to 4, the second etching stop layer 170 is shown to be formed as a single layer, but the present disclosure is not limited thereto. In some other implementations, the second etching stop layer 170 may be formed as a multilayer structure. For example, the second etching stop layer 170 may include at least one of aluminum oxide, aluminum nitride, hafnium oxide, zirconium oxide, silicon oxide, silicon nitride, silicon oxynitride, and low-k dielectric materials.

The second upper interlayer insulating layer 180 may be disposed on the second etching stop layer 170. For example, the second upper interlayer insulating layer 180 may include at least one of silicon oxide, silicon nitride, silicon oxynitride, and low-k dielectric materials. The via V1 may extend through the second upper interlayer insulating layer 180 and the second etching stop layer 170 in the vertical direction DR3 to connect to the gate contact CB. The via V1 may include a conductive material.

In a structure in which source/drain contacts 141, 142 are disposed beneath source/drain regions SD1, SD2, the semiconductor device according to some implementations of the present disclosure may have the air gap 130 formed between adjacent source/drain contacts 141, 142. Accordingly, the semiconductor device according to some implementations of the present disclosure may improve the reliability of the semiconductor device by reducing the capacitance between adjacent source/drain contacts 141, 142.

Hereinafter, a method for fabricating a semiconductor device according to several implementations of the present disclosure will be described with reference to FIGS. 2 to 33.

FIGS. 5 to 33 are intermediate stage diagrams for explaining the method for fabricating a semiconductor device according to some implementations of the present disclosure.

Referring to FIGS. 5 and 6, a substrate 10 may be provided. The substrate 10 may be a silicon substrate or a silicon-on-insulator (SOI) substrate. Alternatively, the substrate 10 may include silicon germanium, silicon germanium on insulator (SGOI), indium antimonide, lead telluride compounds, indium arsenide, indium phosphide, gallium arsenide, or gallium antimonide. However, the present disclosure is not limited thereto. Hereinafter, the substrate 10 will be described as including silicon (Si). Subsequently, a stacked structure 20 may be formed on the upper surface of the substrate 10. The stacked structure 20 may include a first semiconductor layer 21 and a second semiconductor layer 22 alternately stacked on the upper surface of the substrate 10. For example, the first semiconductor layer 21 may be formed at the lowermost portion of the stacked structure 20, and the second semiconductor layer 22 may be formed at the uppermost portion of the stacked structure 20. For example, the first semiconductor layer 21 may include silicon germanium (SiGe), and the second semiconductor layer 22 may include silicon (Si).

Subsequently, a portion of the stacked structure 20 may be etched. While the stacked structure 20 is being etched, a portion of the substrate 10 may also be etched. Through this etching process, the active pattern F1 may be defined beneath the stacked structure 20 on the upper surface of the substrate 10. The active pattern F1 may extend in the first horizontal direction DR1. Then, the field insulating layer 105 may be formed on the upper surface of the substrate 10. The field insulating layer 105 may surround the sidewall of the active pattern F1. For example, the upper surface of the active pattern F1 may be formed higher than the upper surface of the field insulating layer 105. Then, the pad oxide layer 30 may be formed to cover the upper surface of the field insulating layer 105, the sidewalls of the exposed active pattern F1, and the sidewalls and upper surface of the stacked structure 20. For example, the pad oxide layer 30 may be conformally formed. For example, the pad oxide layer 30 may include silicon oxide (SiO₂).

Referring to FIGS. 7 and 8, a dummy gate DG and a dummy capping pattern DC, extending in the second horizontal direction DR2, may be formed on the pad oxide layer 30 over the stacked structure 20 and the field insulating layer 105. The dummy capping pattern DC may be disposed on the dummy gate DG. While the dummy gate DG and the dummy capping pattern DC are being formed, the portions of the pad oxide layer 30 that are not overlapped with the dummy gate DG in the vertical direction DR3 on the substrate 10 may be removed.

Subsequently, a spacer material layer SM may be formed to cover the sidewalls of the dummy gate DG, the sidewalls and upper surface of each dummy capping pattern DC, the exposed sidewall and upper surface of the stacked structure 20, and the upper surface of the field insulating layer 105. For example, the spacer material layer SM may be formed conformally. For example, the spacer material layer SM may include at least one of silicon nitride (SiN), silicon oxycarbonitride (SiOCN), silicon boron carbonitride (SiBCN), silicon carbonitride (SiCN), silicon oxynitride (SiON), or a combination thereof.

Referring to FIGS. 9 and 10, the stacked structure 20 (see FIG. 7) may be etched using the dummy gate DG and the dummy capping pattern DC as masks to form the first and second source/drain trenches ST1, ST2. For example, the first source/drain trench ST1 may be formed on the first side of the dummy gate DG. The second source/drain trench ST2 may be formed on the second side of the dummy gate DG, opposite to the first side of the dummy gate DG in the first horizontal direction DR1. For example, each of the first and second soil/drain trenches ST1, ST2 may extend into the inside of the active pattern F1.

While the first and second source/drain trenches ST1, ST2 are being formed, a portion of the spacer material layer SM (see FIG. 7) formed on the upper surface of the dummy capping pattern DC and a portion the dummy capping pattern DC may be etched. For example, the spacer material layer SM (see FIG. 7) remaining on the sidewall of each dummy capping pattern DC and dummy gate DG may be defined as the gate spacer 111. For example, after forming the first and second source/drain trenches ST1, ST2, the second semiconductor layer 22 (see FIG. 7) remaining beneath the dummy gate DG on the active pattern F1 may be defined as a plurality of nanosheets NW.

Referring to FIGS. 11 and 12, the first source/drain region SD1 may be formed inside the first source/drain trench ST1 (see FIG. 9), and the second source/drain region SD2 may be formed inside the second source/drain trench ST2 (see FIG. 9). Subsequently, the first etching stop layer 150 may be formed on the upper surface of the exposed field insulating layer 105, the sidewall of the exposed gate spacer 111, the upper surface of the exposed dummy capping pattern DC (see FIG. 9), and the surface of each of the exposed first and second source/drain regions SD1, SD2. For example, the first etching stop layer 150 may be formed conformally. Then, the first upper interlayer insulating layer 160 may be formed on the first etching stop layer 150. Subsequently, through a planarization process, the upper surface of the dummy gate DG may be exposed.

Referring to FIGS. 13 and 14, the dummy gate DG (see FIG. 11), the pad oxide 30 (see FIG. 11), and the first semiconductor layer 21 (see FIG. 11) may each be etched. The etched portions of the dummy gate DG (see FIG. 11), the pad oxide 30 (see FIG. 11), and the first semiconductor layer 21 (see FIG. 11) may be defined as the gate trench GT.

Referring to FIGS. 15 and 16, the gate insulating layer 112, the gate electrode G1, and the capping pattern 113 may be sequentially formed inside the gate trench GT (see FIG. 13).

Referring to FIGS. 17 to 19, the gate contact CB may be formed to extend through the capping pattern 113 in the vertical direction DR3 and connect to the gate electrode G1. Subsequently, the second etching stop layer 170 and the second upper interlayer insulating layer 180 may be sequentially formed on the upper surface of each of the first upper interlayer insulating layer 160, the capping pattern 113, and the gate contact CB. Subsequently, the via V1 may be formed to extend through the second etching stop layer 170 and the second upper interlayer insulating layer 180 in the vertical direction DR3 to connect to the gate contact CB.

Referring to FIGS. 20 to 22, the substrate 10 (see FIGS. 17 to 19) may be etched. For example, the substrate 10 (see FIGS. 17 to 19) may be etched through a planarization process. After this etching process is completed, the bottom surface of each of the active pattern F1 and the field insulating layer 105 may be exposed.

Referring to FIGS. 23 and 24, a mask pattern M1 may be formed at the bottom surface of each of the active pattern F1 and the field insulating layer 105. For example, the mask pattern M1 may expose a portion of each of the active pattern F1 and the field insulating layer 105 formed beneath the gate electrode G1. Subsequently, using the mask pattern M1 as a mask, a portion of the active pattern F1 and the field insulating layer 105 may be etched to form an isolation trench T1. For example, the gate insulating layer 112 may be exposed through the upper surface of the isolation trench T1.

Referring to FIGS. 25 and 26, the mask pattern M1 (see FIGS. 23 and 24) may be removed. Then, the liner layer 120 may be formed at the surface of the isolation trench T1, the bottom surface of the active pattern F1, and the bottom surface of the field insulating layer 105. While the liner layer 120 is being formed, the air gap 130, which is surrounded by the liner layer 120 from the inside of the isolation trench T1, may be formed. For example, the bottom surface of the air gap 130 may be formed higher than the bottom surfaces of the active pattern F1 and the field insulating layer 105, respectively.

Referring to FIGS. 27 and 28, the planarization process may be performed to expose the bottom surface of each of the active pattern F1 and the field insulating layer 105. After this etching process is completed, the lowermost surface of the liner layer 120 may be formed on the same plane as each of the bottom surfaces of the active pattern F1 and the field insulating layer 105. For example, after this etching process is completed, the air gap 130 is not exposed.

Referring to FIG. 29 and FIG. 31, the insulating pattern 101 may be formed at the bottom surface of the active pattern F1, the bottom surface of the field insulating layer 105, and the lowermost surface of the liner layer 120. For example, insulating pattern 101 may expose the bottom surface of the active pattern F1 formed beneath each of the first and second source/drain regions SD1, SD2. Subsequently, using the insulating pattern 101 as a mask, the active pattern F1 may be etched to form the first and second contact trenches 141T, 142T. The first contact trench 141T may be formed beneath the first source/drain region SD1, and the second contact trench 142T may be formed beneath the second source/drain region SD2. For example, the first contact trench 141T may extend into the inside of the first source/drain region SD1, and the second contact trench 142T may extend into the inside of the second source/drain region SD2.

Referring to FIGS. 32 and 33, the first source/drain contact 141 may be formed inside the first contact trench 141T (see FIGS. 29 and 31), and the second source/drain contact 142 may be formed inside the second contact trench 142T (see FIG. 29). Additionally, the silicide layer SL may be formed at the interface between the first source/drain contact 141 and the first source/drain region SD1, as well as at the interface between the second source/drain contact 142 and the second source/drain region SD2.

Referring to FIG. 2 to FIG. 4, the lower interlayer insulating layer 100 may be formed at the bottom surface of the insulating pattern 101, the first and second source/drain contacts 141, 142, respectively. Through this fabrication process, the semiconductor devices shown in FIG. 2 to FIG. 4 may be fabricated.

Hereinafter, a semiconductor device according to some other implementations of the present disclosure will be described with reference to FIGS. 34 and 35. The differences from the semiconductor devices shown in FIG. 1 to FIG. 4 will be described.

FIG. 34 and FIG. 35 are cross-sectional views for explaining a semiconductor device according to other implementations of the present disclosure.

Referring to FIGS. 34 and 35, in the semiconductor device according to some other implementations of the present disclosure, the bottom surface of the air gap 230 may be in contact with the upper surface of the insulating pattern 101. In other words, the bottom surface of the air gap 230 may be defined by the upper surface of the insulating pattern 101. For example, the bottom surface of the air gap 230 may be formed on the same plane as the lowermost surface of the liner layer 220.

Hereinafter, a semiconductor device according to several other implementations of the present disclosure will be described with reference to FIG. 36. The differences from the semiconductor devices shown in FIGS. 1 to 4 will be described.

FIG. 36 is a cross-sectional view for explaining a semiconductor device according to several other implementations of the present disclosure.

Referring to FIG. 36, in a semiconductor device according to several other implementations of the present disclosure, each of the first and second source/drain contacts 341, 342 may be in contact with the liner layer 120.

For example, the sidewall of the first source/drain contact 341 in the first horizontal direction DR1 may be in contact with the outer sidewall of the liner layer 120 in the first horizontal direction DR1. Additionally, the sidewall of the second source/drain contact 342 in the first horizontal direction DR1 may be in contact with the outer sidewall of the liner layer 120 in the first horizontal direction DR1. For example, the active pattern F3 may be disposed between the upper portions of the first and second source/drain contacts 341, 342 and the upper outer sidewall of the liner layer 120.

For example, the sidewall of the insulating pattern 301 that is in contact with the first source/drain contact 341 and the sidewall of the liner layer 120 that is in contact with the first source/drain contact 341 may have a continuous sloped profile. Additionally, the sidewall of the insulating pattern 301 that is in contact with the second source/drain contact 342 and the sidewall of the liner layer 120 that is in contact with the second source/drain contact 342 may have a continuous sloped profile. For example, the silicide layer SL3 may be disposed along the interface between the first source/drain contact 341 and the first source/drain region SD1. In addition, the silicide layer SL3 may be disposed along the interface between the second source/drain contact 342 and the second source/drain region SD2.

Hereinafter, a semiconductor device according to another several implementations of the present disclosure will be described with reference to FIGS. 37 and 38. The description will be focused on the differences from the semiconductor devices shown in FIG. 1 to FIG. 4.

FIGS. 37 and 38 are cross-sectional views for explaining a semiconductor device according to another several implementations of the present disclosure.

Referring to FIGS. 37 and 38, in a semiconductor device according to some other implementations of the present disclosure, a contact barrier layer 445 may be disposed on the sidewalls of the first and second source/drain contacts 441, 442.

For example, the contact barrier layer 445 may be disposed between the first source/drain contact 441 and the active pattern F1. The contact barrier layer 445 may be disposed between the first source/drain contact 441 and the insulating pattern 101. Additionally, the contact barrier layer 445 may be disposed between the second source/drain contact 442 and the active pattern 101. The contact barrier layer 445 may be disposed between the second source/drain contact 442 and the insulating pattern 101.

For example, the bottom surface of the contact barrier layer 445 may be formed on the same plane as the bottom surface of the first and second source/drain contacts 441, 442, respectively. For example, the bottom surface of the contact barrier layer 445 may be in contact with the upper surface of the lower interlayer insulating layer 100. The contact barrier layer 445 may include an insulating material. The contact barrier layer 445 may include at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), or combinations thereof. However, the present disclosure is not limited thereto.

Hereinafter, a semiconductor device according to several other implementations of the present disclosure will be described with reference to FIG. 39. The differences from the semiconductor device shown in FIGS. 1 to 4 will be described.

FIG. 39 is a cross-sectional view for explaining the semiconductor device according to several other implementations of the present disclosure.

Referring to FIG. 39, in the semiconductor device according to several other implementations of the present disclosure, an inner spacer 590 may be disposed between each of the first and second source/drain regions SD1, SD2 and the gate electrode G5.

For example, the inner spacer 590 may be disposed on both sidewalls of the gate electrode G5 in the first horizontal direction DR1, between the upper surface of the active pattern F1 and the bottom surface of the lowermost nanosheet of the plurality of nanosheets NW. Additionally, the inner spacer 590 may be disposed on both sidewalls of the gate electrode G5 in the first horizontal direction DR1, between adjacent plurality of nanosheets NW. The inner spacer 590 may be in contact with the plurality of nanosheets NW, the first and second source/drain regions SD1, SD2, and the gate insulating layer 512, respectively. For example, the inner spacer 590 may include at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), or combinations thereof.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although the implementations of the present disclosure have been described above with reference to the accompanying drawings, it will be understood that the present disclosure is not limited to these implementations and may be implemented in various other forms. Those skilled in the art to which the present disclosure pertains will recognize that it can be implemented in other specific forms without departing from its technical concept or essential features. Accordingly, the above-described implementations should be understood as illustrative rather than restrictive in all respects.

### BRIEF DESCRIPTION OF THE DRAWINGS

The above and other aspects and features of the present disclosure will become more apparent by describing in detail exemplary implementations thereof with reference to the attached drawings, in which:

FIG. 1 is a layout diagram for explaining a semiconductor device according to some implementations of the present disclosure;

FIG. 2 is a cross-sectional view taken along line A-A' of FIG. 1;

FIG. 3 is a cross-sectional view taken along line B-B' of FIG. 1;

FIG. 4 is a cross-sectional view taken along line C-C' of FIG. 1;

FIGS. 5 to 33 are intermediate stage diagrams for explaining a method for fabricating a semiconductor device according to some implementations of the present disclosure;

FIGS. 34 and 35 are cross-sectional views for explaining a semiconductor device according to other implementations of the present disclosure;

FIG. 36 is a cross-sectional view for explaining a semiconductor device according to some other implementations of the present disclosure;

FIGS. 37 and 38 are cross-sectional views for explaining a semiconductor device according to some other implementations of the present disclosure; and

FIG. 39 is a cross-sectional view for explaining a semiconductor device according to some other implementations of the present disclosure.

### DETAILED DESCRIPTION

In the diagrams of the semiconductor device according to some of the following implementations, the semiconductor device is described by way of example as including a transistor (MBCFET^{TM} (Multi-Bridge Channel Field Effect Transistor)) that includes a nanosheet. However, this is not intended to limit the present disclosure. In other implementations, the semiconductor device may include a Fin-type transistor (FinFET) having a channel region in the shape of a fin pattern, a tunneling transistor (tunneling FET), or a three-dimensional (3D) structured transistor. Additionally, the semiconductor device according to some other implementations may include a bipolar junction transistor or a lateral double-diffused metal-oxide-semiconductor (LDMOS) transistor.

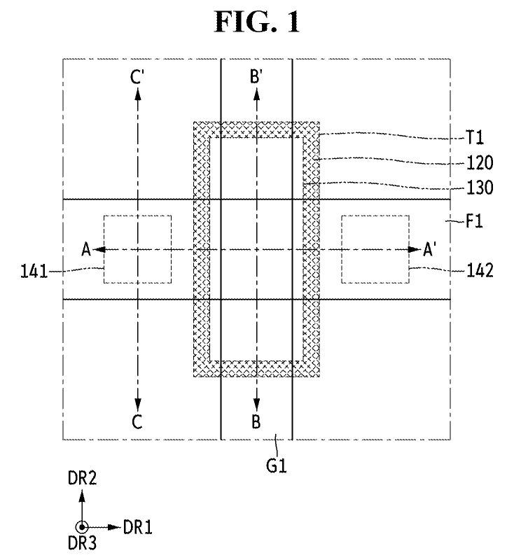

Hereinafter, the semiconductor device according to some implementations of the present disclosure is described with reference to FIGS. 1 to 4.

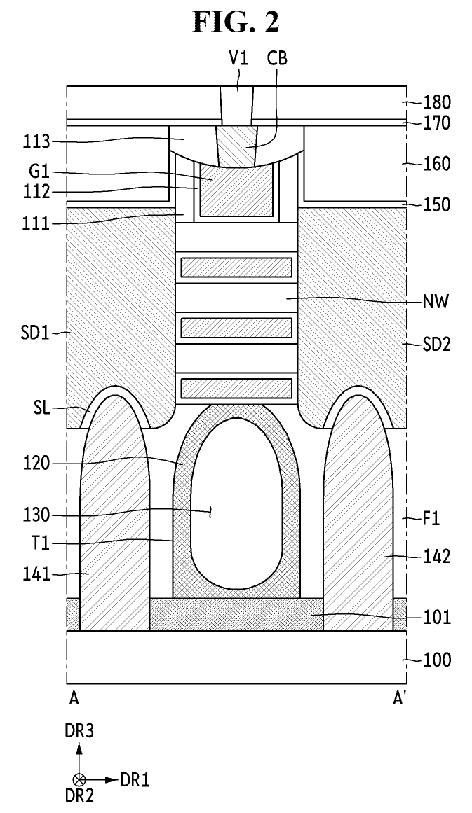

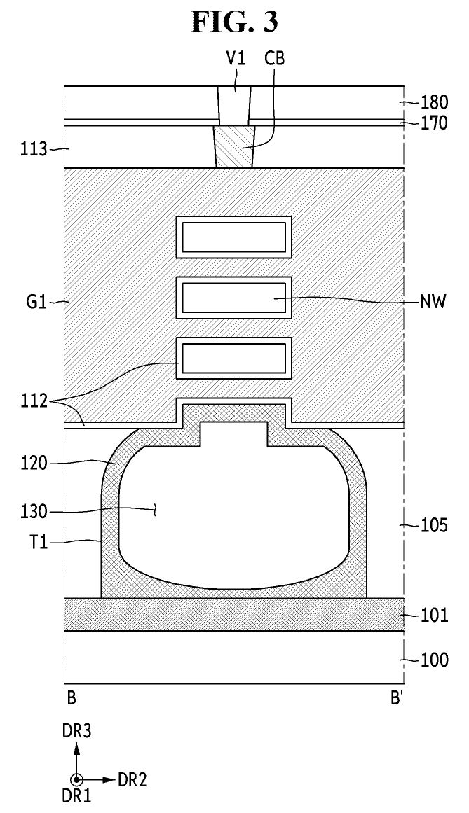

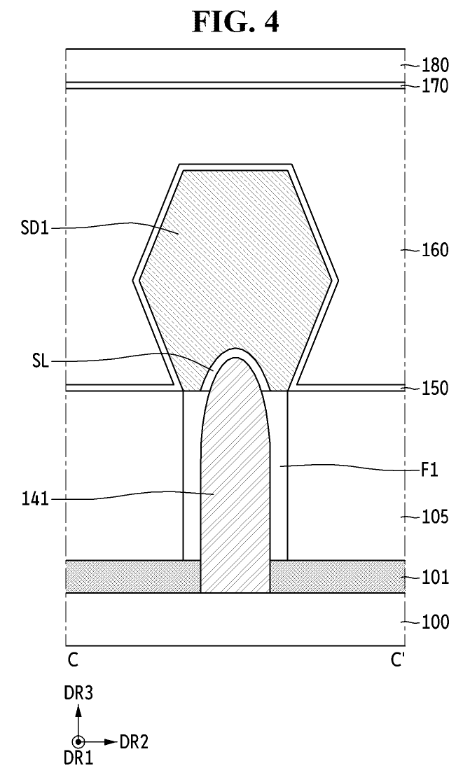

FIG. 1 is a layout diagram for explaining a semiconductor device according to some implementations of the present disclosure. FIG. 2 is a cross-sectional view taken along line A-A' in FIG. 1. FIG. 3 is a cross-sectional view taken along line B-B' in FIG. 1. FIG. 4 is a cross-sectional view taken along line C-C' in FIG. 1.

Referring to FIG. 1 to FIG. 4, the semiconductor device according to some implementations of the present disclosure includes a lower interlayer insulating layer 100, an insulating pattern 101, an active pattern F1, a field insulating layer 105, a plurality of nanosheets NW, first and second source/drain regions SD1, SD2, a gate electrode G1, a gate spacer 111, a gate insulating layer 112, a capping pattern 113, an isolation trench T1, a liner layer 120, an air gap 130, first and second source/drain contacts 141, 142, a silicide layer SL, a first etching stop layer 150, a first upper interlayer insulating layer 160, a gate contact CB, a second etching stop layer 170, a second upper interlayer insulating layer 180, and a via V1.

For example, the interlayer insulating layer 100 may include at least one of silicon oxide, silicon nitride, silicon oxynitride, and low-k dielectric materials. Low-k dielectric materials may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylCycloTetraSiloxane (OMCTS), HexaMethylDiSiloxane (HMDS), TriMethylSilyl Borate (TMSB), DiAcetoxyDitertiaryButoxySiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica, or combinations thereof, however, this is not intended to limit the scope of the disclosure.

Hereinafter, the first horizontal direction DR1 and the second horizontal direction DR2 may be defined as being parallel to the upper surface of the lower interlayer insulating layer 100. The second horizontal direction DR2 may be defined as a direction different from the first horizontal direction DR1. The vertical direction DR3 may be defined as a direction perpendicular to both the first horizontal direction DR1 and the second horizontal direction DR2. In other words, the vertical direction DR3 may be defined as a direction perpendicular to the upper surface of the lower interlayer insulating layer 100.

The insulating pattern 101 may be disposed on the upper surface of the lower interlayer insulating layer 100. For example, the bottom surface of the insulating pattern 101 may be in contact with the upper surface of the lower interlayer insulating layer 100. The insulating pattern 101 may include an insulating material. For example, the insulating pattern 101 may include a material used as a mask. For example, the insulating pattern 101 may include silicon oxide (SiO₂), silicon nitride (SiN), silicon oxynitride (SiON), silicon oxycarbonitride (SiOCN), or silicon carbonitride (SiCN), but the present disclosure is not limited to these. The active pattern F1 may extend in the first horizontal direction DR1 on the upper surface of the insulating pattern 101. The bottom surface of the active pattern F1 may be in contact with the upper surface of the insulating pattern 101. For example, the active pattern F1 may include silicon (Si). In some other implementations, the active pattern F1 may also include silicon germanium (SiGe).

The field insulating layer 105 may be disposed on the upper surface of the insulating pattern 101. The field insulating layer 105 may surround the sidewall of the active pattern F1. For example, the field insulating layer 105 may be in contact with the sidewall of the active pattern F1 in the second horizontal direction DR2. For example, the field insulating layer 105 may be in contact with the outer sidewall of the liner layer 120 in the second horizontal direction DR2 as described later. For example, the upper surface of the field insulating layer 105 may be lower than the upper surface of the active pattern F1. In other words, at least a portion of the active pattern F1 may protrude in the vertical direction DR3 above the upper surface of the field insulating layer 105. However, the present disclosure is not limited thereto. In some other implementations, the upper surface of the field insulating layer 105 may be formed on the same plane as the upper surface of the active pattern F1. For example, the field insulating layer 105 may include an oxide layer, a nitride layer, an oxynitride layer, or a combination thereof.

A plurality of nanosheets NW may be disposed on the upper surface of the active pattern F1. The plurality of nanosheets NW may be disposed at the intersection of the active pattern F1 and the gate electrode G1. The plurality of nanosheets NW may include a plurality of nanosheets stacked apart from each other in the vertical direction DR3. In FIGS. 2 and 3, it is shown that the plurality of nanosheets NW includes three nanosheets stacked and spaced apart from each other in the vertical direction DR3, but this is for the convenience of explanation and the present disclosure is not limited to this. In some other implementations, the plurality of nanosheets NW may include four or more nanosheets stacked and spaced apart from each other in the vertical direction DR3. For example, the plurality of nanosheets NW may include silicon (Si). In some other implementations, the plurality of nanosheets NW may include silicon germanium (SiGe).

The gate electrode G1 may extend in the second horizontal direction DR2 on the active pattern F1 and the field insulating layer 105. The gate electrode G1 may surround the plurality of nanosheets NW. For example, the gate electrode G1 may contain one or more of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. The gate electrode G1 may contain conductive metal oxides, conductive metal nitrides, or similar materials, and may also contain the oxidized forms of the aforementioned materials.

The gate spacer 111 may extend in the second horizontal direction DR2 along both sidewalls of the gate electrode G1 on the upper surface of the uppermost nanosheet of the plurality of nanosheets and on the upper surface of the field insulating layer 105. For example, the gate spacer 111 may include at least one of silicon nitride (SiN), silicon oxide (SiO₂), silicon oxycarbonitride (SiOCN), silicon boron nitride (SiBN), silicon oxyboron nitride (SiOBN), silicon oxycarbide (SiOC), and combinations thereof. However, the present disclosure is not limited thereto.

The first source/drain region SD1 may be disposed on the first side of the gate electrode G1 on the active pattern F1. The second source/drain region SD2 may be disposed on the second side of the gate electrode G1 opposite to the first side of the gate electrode G1 in the first horizontal direction DR1 on the active pattern F1. The first and second source/drain regions SD1, SD2 may be in contact with both sidewalls of the plurality of nanosheets NW in the first horizontal direction DR1. For example, the upper surface of each of the first and second source/drain regions SD1, SD2 may be formed higher than the upper surface of the uppermost nanosheet of the plurality of nanosheets.

The gate insulating layer 112 may be disposed between the gate electrode G1 and the gate spacer 111. The gate insulating layer 112 may be disposed between the gate electrode G1 and the active pattern F1. The gate insulating layer 112 may be disposed between the gate electrode G1 and the field insulating layer 105. The gate insulating layer 112 may be disposed between the gate electrode G1 and a plurality of nanosheets NW. The gate insulating layer 112 may be disposed between the gate electrode G1 and the first source/drain region SD1. The gate insulating layer 112 may be disposed between the gate electrode G1 and the second source/drain region SD2. The gate insulating layer 112 may be disposed between the gate electrode G1 and a liner layer 120, which will be described later.

The gate insulating layer 112 may include at least one of silicon oxide, silicon oxynitride, silicon nitride, or a high-k dielectric material having a dielectric constant greater than that of silicon oxide. The high-k dielectric material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The semiconductor device according to some other implementations may include an NC (Negative Capacitance) FET using a negative capacitor. For example, the gate insulating layer 112 may include a ferroelectric material layer having ferroelectric properties and a paraelectric material layer having paraelectric properties.

The ferroelectric material layer may exhibit negative capacitance, while the paraelectric material layer may exhibit positive capacitance. For example, when two or more capacitors are connected in series and each of their capacitances has a positive value, the overall capacitance decreases relative to the capacitance of each individual capacitor. On the other hand, if the capacitances of at least one of the two or more capacitors connected in series has a negative value, the overall capacitance may be greater than the absolute value of each individual capacitance while still being positive.

When the ferroelectric material layer with negative capacitance and the paraelectric material layer with positive capacitance are connected in series, the overall capacitance value of the ferroelectric material layer and the paraelectric material layer connected in series may increase. By utilizing the increase in overall capacitance value, the transistor including the ferroelectric material layer may have a subthreshold swing (SS) of less than 60 mV/decade at room temperature.

The ferroelectric material layer may have ferroelectric properties. The ferroelectric material layer may include, for example, at least one of hafnium oxide, hafnium zirconium oxide, barium strontium titanium oxide, barium titanium oxide, and lead zirconium titanium oxide. As another example, hafnium zirconium oxide may be a material in which zirconium (Zr) is doped into hafnium oxide. In another example, hafnium zirconium oxide may be a compound of hafnium (Hf) and zirconium (Zr) combined with oxygen (O).

The ferroelectric material layer may further include a dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). Depending on which ferroelectric material the ferroelectric material layer contains, the type of dopant contained in the ferroelectric material layer may vary.

If the ferroelectric material layer includes hafnium oxide, the dopant included in the ferroelectric material layer may include, for example, at least one of gadolinium (Gd), silicon (Si), zirconium (Zr), aluminum (Al), and yttrium (Y).

If the dopant is aluminum (Al), the ferroelectric material layer may contain about 3 to 8 at% aluminum. (atomic %). Here, the ratio of the dopant may be a ratio of aluminum relative to the sum of hafnium and aluminum.

If the dopant is silicon (Si), the ferroelectric material layer may contain 2 to 10 at% of silicon. If the dopant is yttrium (Y), the ferroelectric material layer may contain 2 to 10 at% of yttrium. If the dopant is gadolinium (Gd), the ferroelectric material layer may contain 1 to 7 at% of gadolinium. If the dopant is zirconium (Zr), the ferroelectric material layer may contain 50 to 80 at% of zirconium.

The paraelectric material layer may have paraelectric properties. The paraelectric material layer may include, for example, at least one or more of silicon oxide and metal oxides with a high-k dielectric constant. The metal oxides contained in the paraelectric material layer may include, for example, at least one of hafnium oxide, zirconium oxide, and aluminum oxide, but is not limited thereto.

The ferroelectric material layer and the paraelectric material layer may include the same material. While the ferroelectric material layer may have ferroelectric properties, the paraelectric material layer may not have ferroelectric properties. For example, if both the ferroelectric material layer and the paraelectric material layer contain hafnium oxide, the crystal structure of the hafnium oxide included in the ferroelectric material layer is different from the crystal structure of the hafnium oxide included in the paraelectric material layer.

The ferroelectric material layer may have a thickness sufficient to exhibit ferroelectric properties. For example, the thickness of the ferroelectric material layer may range from 0.5 to 10 nm, but is not limited thereto. Since the critical thickness for exhibiting ferroelectric properties may vary depending on the ferroelectric material, the thickness of the ferroelectric material layer may also vary depending on the specific ferroelectric material used.

For example, the gate insulating layer 112 may include a single ferroelectric material layer. In another example, the gate insulating layer 112 may include multiple ferroelectric material layers spaced apart from each other. The gate insulating layer 112 may have a stacked structure in which multiple ferroelectric material layers and multiple paraelectric material layers are alternately stacked.

The first etching stop layer 150 may be disposed on the sidewall of the gate spacer 111. The first etching stop layer 150 may be disposed on the upper surface of the field insulating layer 105. The first etching stop layer 150 may be disposed on the upper surface of each of the first and second source/drain regions SD1, SD2. The first etching stop layer 150 may be disposed on the sidewall of each of the first and second source/drain regions SD1, SD2 in the second horizontal direction DR2. For example, the first etching stop layer 150 may be formed in a conformal manner. For example, the first etching stop layer 150 may include at least one of aluminum oxide, aluminum nitride, hafnium oxide, zirconium oxide, silicon oxide, silicon nitride, silicon oxynitride, and low-k dielectric materials.

The capping pattern 113 may extend in the second horizontal direction DR2 on each of the gate spacer 111, the gate insulating layer 112 and the gate electrode G1. For example, the bottom surface of the capping pattern 113 may be in contact with the first etching stop layer 150. However, the present disclosure is not limited thereto. In some other implementations, the sidewall of the capping pattern 113 may be in contact with the first etching stop layer 150. For example, the capping pattern 113 may include at least one of silicon nitride (SiN), silicon oxynitride (SiON), silicon oxide (SiO₂), silicon carbonitride (SiCN), silicon oxycarbonitride (SiOCN), and combinations thereof. However, the present disclosure is not limited thereto.

The first upper interlayer insulating layer 160 may be disposed on the first etching stop layer 150. The first upper interlayer insulating layer 160 may be disposed on the sidewall of the capping pattern 113. The first upper interlayer insulating layer 160 may cover each of the first and second source/drain regions SD1, SD2 on the field insulating layer 105. For example, the upper surface of the first upper interlayer insulating layer 160 may be formed on the same plane as the upper surface of the capping pattern 113. For example, the first upper interlayer insulating layer 160 may include at least one of silicon oxide, silicon nitride, silicon oxynitride, and low-k dielectric materials.

The gate contact CB may pass through the capping pattern 113 in the vertical direction DR3 and be connected to the gate electrode G1. For example, the upper surface of the gate contact CB may be formed on the same plane as the upper surface of the capping pattern 113. However, the present disclosure is not limited thereto. In some other implementations, the upper surface of the gate contact CB may be formed higher than the upper surface of the capping pattern 113. In FIGS. 2 and 3, the gate contact CB is shown to be formed as a single layer, but the present disclosure is not limited thereto. In some other implementations, the gate contact CB may be formed as a multiple layer. The gate contact CB may contain a conductive material.

The first source/drain contact 141 may be disposed beneath the first source/drain region SD1. The first source/drain contact 141 may pass through the active pattern F1 and the insulating pattern 101 in the vertical direction DR3. In other words, the sidewall of the first source/drain contact 141 may be surrounded by the active pattern F1 and the insulating pattern 101. For example, at least a portion of the first source/drain contact 141 may extend into the inside of the first source/drain region SD1. The first source/drain contact 141 may be electrically connected to the first source/drain region SD1.

The second source/drain contact 142 may be disposed beneath the second source/drain region SD2. The second source/drain contact 142 may be spaced apart from the first source/drain contact 141 in the first horizontal direction DR1. The second source/drain contact 142 may pass through the active pattern F1 and insulating pattern 101 in the vertical direction DR3. In other words, the sidewall of the second source/drain contact 142 may be surrounded by the active pattern F1 and the insulating pattern 101. For example, at least a portion of the second source/drain contact 142 may extend into the inside of the second source/drain region SD2. The second source/drain contact 142 may be electrically connected to the second source/drain region SD2.

For example, the bottom surface of each of the first and second source/drain contacts 141, 142 may be formed on the same plane as the bottom surface of the insulating pattern 101. In FIG. 2 and FIG. 4, it is shown that each of the first and second source/drain contacts 141, 142 is formed as a single layer, but the present disclosure is not limited thereto. In some other implementations, each of the first and second source/drain contacts 141, 142 may be formed as multiple layers. Each of the first and second source/drain contacts 141, 142 may include a conductive material. A silicide layer SL may be disposed along the interface between the first source/drain contact 141 and the first source/drain region SD1. Additionally, the silicide layer SL may be disposed along the interface between the second source/drain contact 142 and the second source/drain region SD2. For example, the silicide layer SL may include a metal silicide material.

An isolation trench T1 may be formed between the first source/drain contact 141 and the second source/drain contact 142. The isolation trench T1 may be formed beneath each of the plurality of nanosheets NW and gate electrodes G1. The isolation trench T1 may pass through the active pattern F1 and the field insulating layer 105 and extend in the vertical direction DR3 to the uppermost surface of the active pattern F1. For example, the isolation trench T1 may extend in the second horizontal direction DR2. For example, the isolation trench T1 may be spaced apart from each of the first and second source/drain contacts 141, 142 in the first horizontal direction DR1. For example, the isolation trench T1 may separate the active pattern F1 in the first horizontal direction DR1.

For example, the upper surface of the isolation trench T1 may be defined by the gate insulating layer 112. The sidewalls of the isolation trench T1 in the first horizontal direction DR1 may be defined by an active pattern F1. The sidewalls of the isolation trench T1 in the second horizontal direction DR2 may be defined by the field insulating layer 105. The bottom surface of the isolation trench T1 may be defined by the insulating pattern 101. For example, the bottom surface of the isolation trench T1 may be formed higher than the bottom surface of each of the first and second source/drain contacts 141, 142. For example, at least a portion of the isolation trench T1 may overlap with each of the first and second source/drain regions SD1, SD2 in the first horizontal direction DR1. For example, at least a portion of the isolation trench T1 may overlap with the gate electrode G1 in the second horizontal direction DR2, but the present disclosure is not limited thereto.

For example, the width of the upper surface of the isolation trench T1 in the first horizontal direction DR1 may be smaller than the width of the bottom surface of the isolation trench T1 in the first horizontal direction DR1. The width of the upper surface of the isolation trench T1 in the second horizontal direction DR2 may be smaller than the width of the bottom surface of the isolation trench T1 in the second horizontal direction DR2. The width of the bottom surface of the isolation trench T1 in the second horizontal direction DR2 may be greater than the width of each of the first and second source/drain contacts 141, 142 in the second horizontal direction DR2. The width of the bottom surface of the isolation trench T1 in the second horizontal direction DR2 may be greater than the width of the active pattern F1 in the second horizontal direction DR2.

An air gap 130 may be formed inside the isolation trench T1. In other words, the air gap 130 may be formed between the first source/drain contact 141 and the second source/drain contact 142. The air gap 130 may be formed beneath each of the plurality of nanosheets NW and the gate electrode G1. In other words, the air gap 130 may overlap with each of the plurality of nanosheets NW and the gate electrode G1 in the vertical direction DR3. For example, the air gap 130 may extend in the second horizontal direction DR2. For example, the air gap 130 may be spaced apart from each of the first and second source/drain contacts 141, 142 in the first horizontal direction DR1.

For example, the air gap 130 may be spaced apart from the active pattern F1 in the first horizontal direction DR1. The air gap 130 may be spaced apart from the field insulating layer 105 in the second horizontal direction DR2. For example, the air gap 130 may be spaced apart from the gate insulating layer 112 in the vertical direction DR3. For example, the air gap 130 may be spaced apart from the upper surface of the insulating pattern 101 in the vertical direction DR3. For example, the bottom surface of the air gap 130 may be formed higher than the upper surface of the insulating pattern 101. For example, the width of the air gap 130 in the second horizontal direction DR2 may be greater than the width of each of the first and second source/drain contacts 141, 142 in the second horizontal direction DR2. The width of the air gap 130 in the second horizontal direction DR2 may be greater than the width of the active pattern F1 in the second horizontal direction DR2.

The liner layer 120 may be disposed inside the isolation trench T1. For example, the liner layer 120 may be disposed along the sidewalls and the upper surface of the isolation trench T1. Additionally, the liner layer 120 may be disposed along the bottom surface of the isolation trench T1. The liner layer 120 may surround the surface of the air gap 130. In other words, the air gap 130 may be defined as the space surrounded by the liner layer 120. For example, the outer sidewall of the liner layer 120 in the first horizontal direction DR1 may be spaced apart from each of the first and second source/drain contacts 141, 142 in the first horizontal direction DR1. For example, at least a portion of the active pattern F1 may be disposed between each of the first and second source/drain contacts 141, 142 and the liner layer 120.

For example, the outer sidewall of the liner layer 120 in the first horizontal direction DR1 may be in contact with the active pattern F1. The outer sidewall of the liner layer 120 in the second horizontal direction DR2 may be in contact with the field insulating layer 105. The uppermost surface of the liner layer 120 may be in contact with the gate insulating layer 112. In other words, the gate insulating layer 112 may be disposed between the uppermost surface of the liner layer 120 and the gate electrode G1. For example, the lowermost surface of the liner layer 120 may be in contact with the upper surface of the insulating pattern 101. In other words, the lowermost surface of the liner layer 120 may be formed higher than the bottom surfaces of the first and second source/drain contacts 141, 142, respectively. For example, at least a portion of the liner layer 120 may be disposed between the air gap 130 and the gate electrode G1. In other words, at least a portion of the liner layer 120 may be disposed between the air gap 130 and the gate insulating layer 112.

The liner layer 120 may include insulating materials. For example, the liner layer 120 may contain carbon (C) atoms. For example, the liner layer 120 may include silicon oxycarbide (SiOC), silicon carbide (SiC), silicon carbonitride (SiCN), or silicon oxycarbonitride (SiOCN). In some other implementations, the liner layer 120 may also include silicon nitride (SiN) or silicon oxide (SiO₂).

The second etching stop layer 170 may be disposed on the upper surfaces of the first upper interlayer insulating layer 160, the capping pattern 113, and the gate contact CB, respectively. In FIGS. 2 to 4, the second etching stop layer 170 is shown to be formed as a single layer, but the present disclosure is not limited thereto. In some other implementations, the second etching stop layer 170 may be formed as a multilayer structure. For example, the second etching stop layer 170 may include at least one of aluminum oxide, aluminum nitride, hafnium oxide, zirconium oxide, silicon oxide, silicon nitride, silicon oxynitride, and low-k dielectric materials.

The second upper interlayer insulating layer 180 may be disposed on the second etching stop layer 170. For example, the second upper interlayer insulating layer 180 may include at least one of silicon oxide, silicon nitride, silicon oxynitride, and low-k dielectric materials. The via V1 may extend through the second upper interlayer insulating layer 180 and the second etching stop layer 170 in the vertical direction DR3 to connect to the gate contact CB. The via V1 may include a conductive material.

In a structure in which source/drain contacts 141, 142 are disposed beneath source/drain regions SD1, SD2, the semiconductor device according to some implementations of the present disclosure may have the air gap 130 formed between adjacent source/drain contacts 141, 142. Accordingly, the semiconductor device according to some implementations of the present disclosure may improve the reliability of the semiconductor device by reducing the capacitance between adjacent source/drain contacts 141, 142.

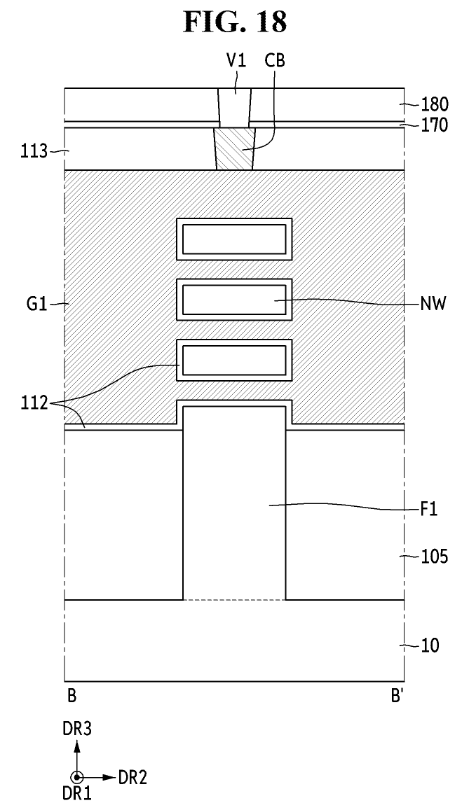

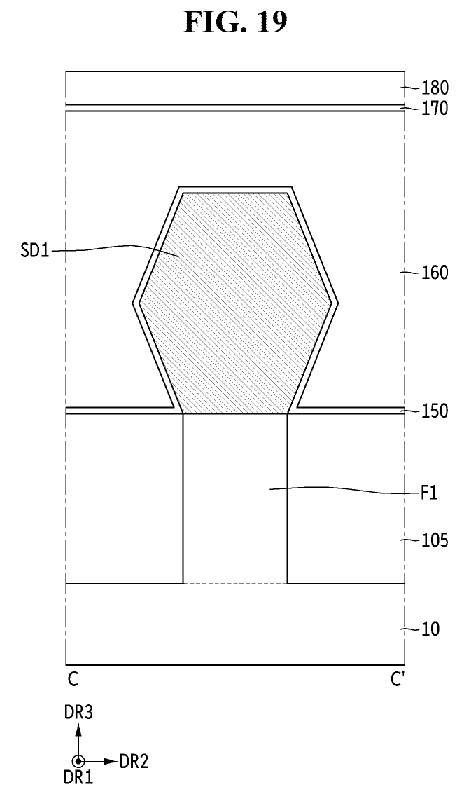

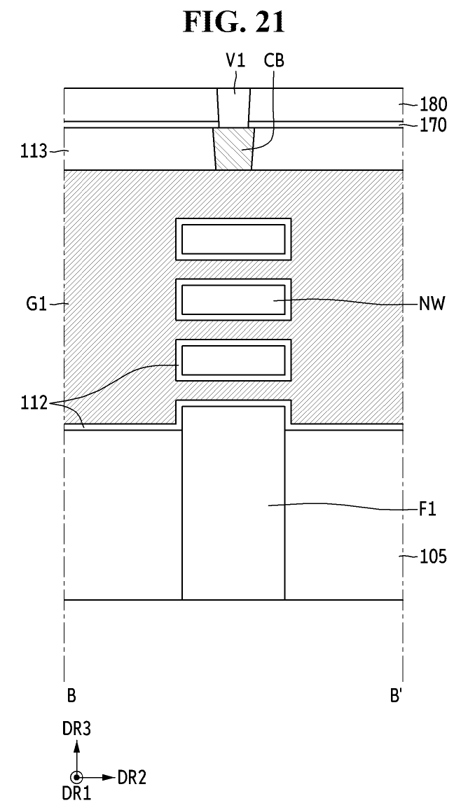

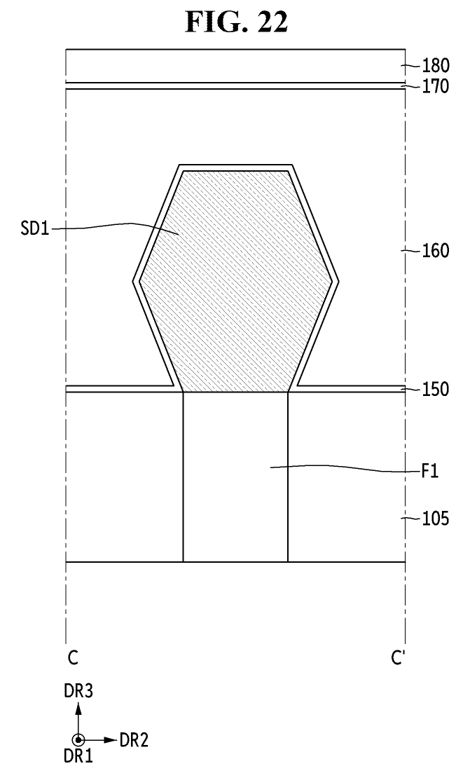

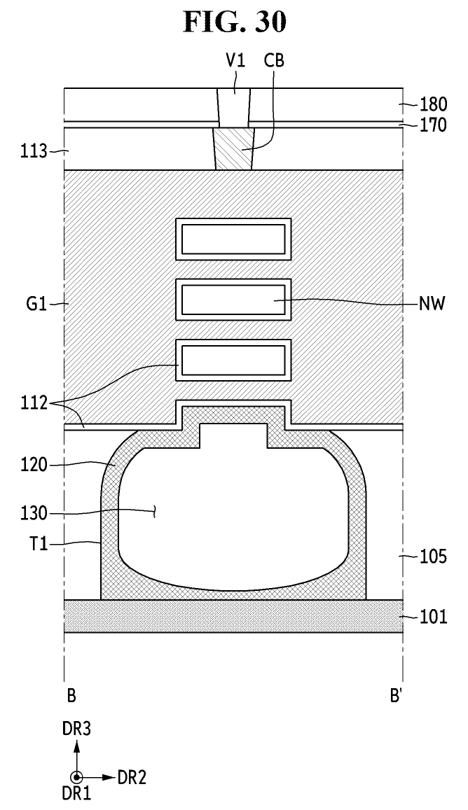

Hereinafter, a method for fabricating a semiconductor device according to several implementations of the present disclosure will be described with reference to FIGS. 2 to 33.

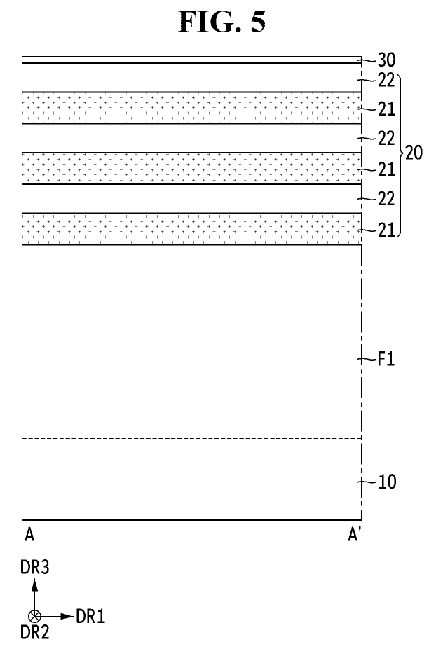

FIGS. 5 to 33 are intermediate stage diagrams for explaining the method for fabricating a semiconductor device according to some implementations of the present disclosure.

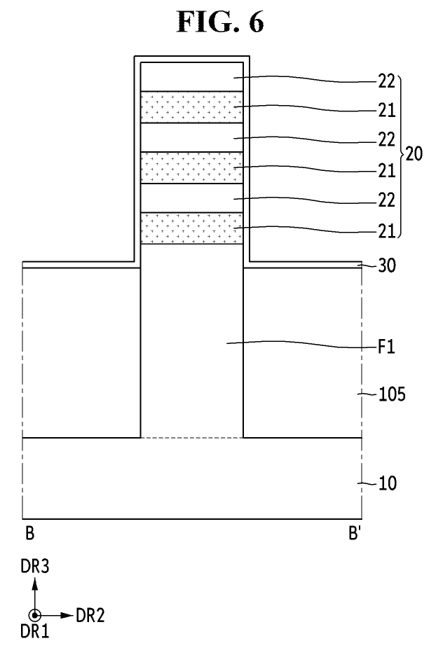

Referring to FIGS. 5 and 6, a substrate 10 may be provided. The substrate 10 may be a silicon substrate or a silicon-on-insulator (SOI) substrate. Alternatively, the substrate 10 may include silicon germanium, silicon germanium on insulator (SGOI), indium antimonide, lead telluride compounds, indium arsenide, indium phosphide, gallium arsenide, or gallium antimonide. However, the present disclosure is not limited thereto. Hereinafter, the substrate 10 will be described as including silicon (Si). Subsequently, a stacked structure 20 may be formed on the upper surface of the substrate 10. The stacked structure 20 may include a first semiconductor layer 21 and a second semiconductor layer 22 alternately stacked on the upper surface of the substrate 10. For example, the first semiconductor layer 21 may be formed at the lowermost portion of the stacked structure 20, and the second semiconductor layer 22 may be formed at the uppermost portion of the stacked structure 20. For example, the first semiconductor layer 21 may include silicon germanium (SiGe), and the second semiconductor layer 22 may include silicon (Si).

Subsequently, a portion of the stacked structure 20 may be etched. While the stacked structure 20 is being etched, a portion of the substrate 10 may also be etched. Through this etching process, the active pattern F1 may be defined beneath the stacked structure 20 on the upper surface of the substrate 10. The active pattern F1 may extend in the first horizontal direction DR1. Then, the field insulating layer 105 may be formed on the upper surface of the substrate 10. The field insulating layer 105 may surround the sidewall of the active pattern F1. For example, the upper surface of the active pattern F1 may be formed higher than the upper surface of the field insulating layer 105. Then, the pad oxide layer 30 may be formed to cover the upper surface of the field insulating layer 105, the sidewalls of the exposed active pattern F1, and the sidewalls and upper surface of the stacked structure 20. For example, the pad oxide layer 30 may be conformally formed. For example, the pad oxide layer 30 may include silicon oxide (SiO₂).

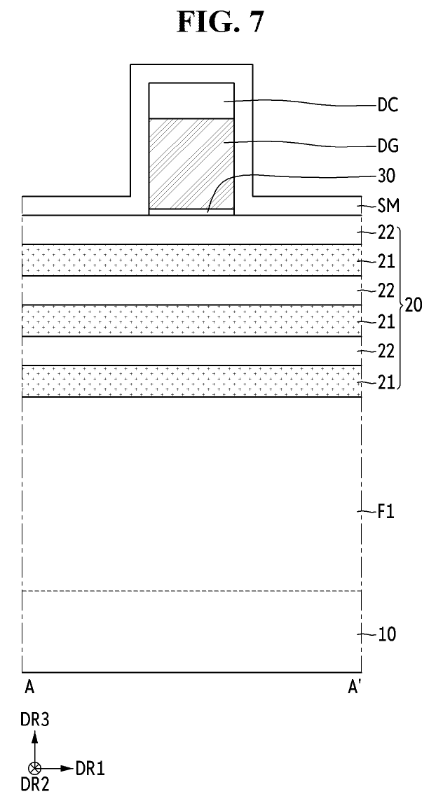

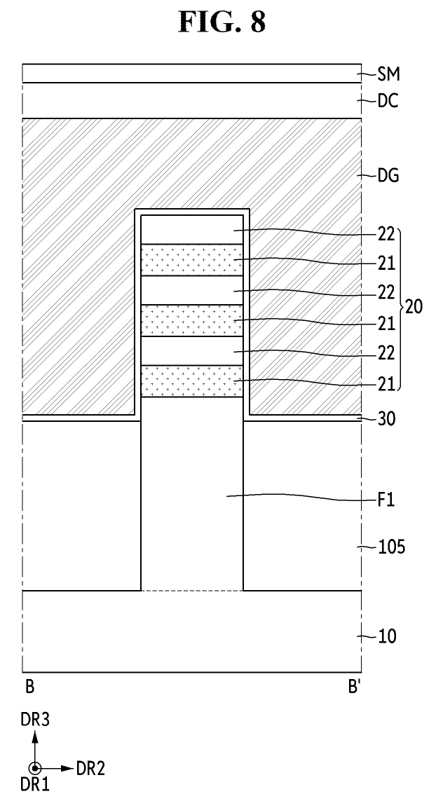

Referring to FIGS. 7 and 8, a dummy gate DG and a dummy capping pattern DC, extending in the second horizontal direction DR2, may be formed on the pad oxide layer 30 over the stacked structure 20 and the field insulating layer 105. The dummy capping pattern DC may be disposed on the dummy gate DG. While the dummy gate DG and the dummy capping pattern DC are being formed, the portions of the pad oxide layer 30 that are not overlapped with the dummy gate DG in the vertical direction DR3 on the substrate 10 may be removed.

Subsequently, a spacer material layer SM may be formed to cover the sidewalls of the dummy gate DG, the sidewalls and upper surface of each dummy capping pattern DC, the exposed sidewall and upper surface of the stacked structure 20, and the upper surface of the field insulating layer 105. For example, the spacer material layer SM may be formed conformally. For example, the spacer material layer SM may include at least one of silicon nitride (SiN), silicon oxycarbonitride (SiOCN), silicon boron carbonitride (SiBCN), silicon carbonitride (SiCN), silicon oxynitride (SiON), or a combination thereof.

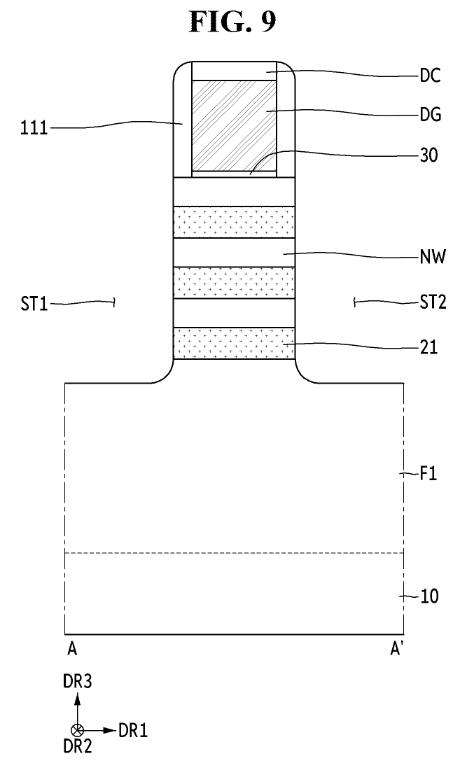

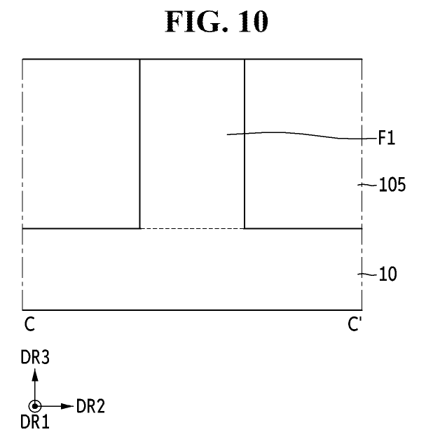

Referring to FIGS. 9 and 10, the stacked structure 20 (see FIG. 7) may be etched using the dummy gate DG and the dummy capping pattern DC as masks to form the first and second source/drain trenches ST1, ST2. For example, the first source/drain trench ST1 may be formed on the first side of the dummy gate DG. The second source/drain trench ST2 may be formed on the second side of the dummy gate DG, opposite to the first side of the dummy gate DG in the first horizontal direction DR1. For example, each of the first and second soil/drain trenches ST1, ST2 may extend into the inside of the active pattern F1.

While the first and second source/drain trenches ST1, ST2 are being formed, a portion of the spacer material layer SM (see FIG. 7) formed on the upper surface of the dummy capping pattern DC and a portion the dummy capping pattern DC may be etched. For example, the spacer material layer SM (see FIG. 7) remaining on the sidewall of each dummy capping pattern DC and dummy gate DG may be defined as the gate spacer 111. For example, after forming the first and second source/drain trenches ST1, ST2, the second semiconductor layer 22 (see FIG. 7) remaining beneath the dummy gate DG on the active pattern F1 may be defined as a plurality of nanosheets NW.

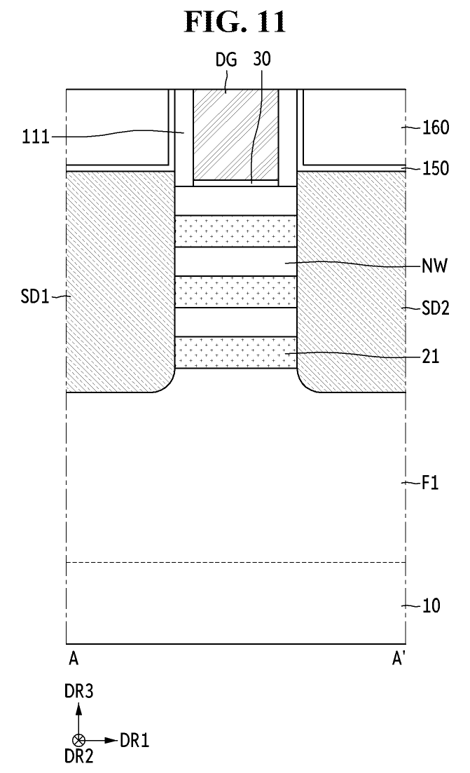

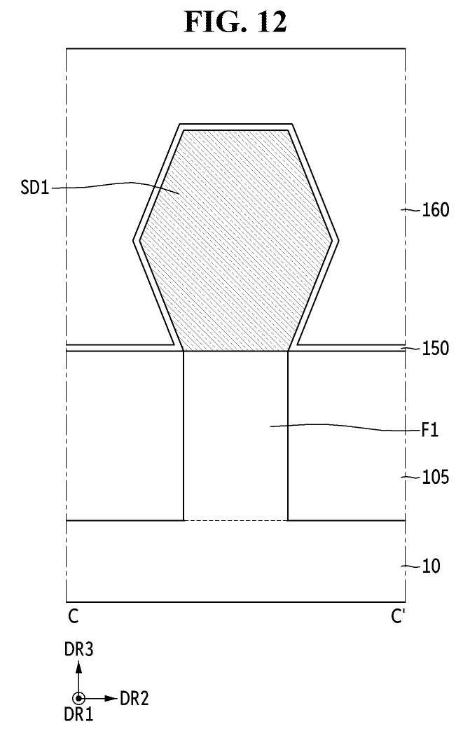

Referring to FIGS. 11 and 12, the first source/drain region SD1 may be formed inside the first source/drain trench ST1 (see FIG. 9), and the second source/drain region SD2 may be formed inside the second source/drain trench ST2 (see FIG. 9). Subsequently, the first etching stop layer 150 may be formed on the upper surface of the exposed field insulating layer 105, the sidewall of the exposed gate spacer 111, the upper surface of the exposed dummy capping pattern DC (see FIG. 9), and the surface of each of the exposed first and second source/drain regions SD1, SD2. For example, the first etching stop layer 150 may be formed conformally. Then, the first upper interlayer insulating layer 160 may be formed on the first etching stop layer 150. Subsequently, through a planarization process, the upper surface of the dummy gate DG may be exposed.

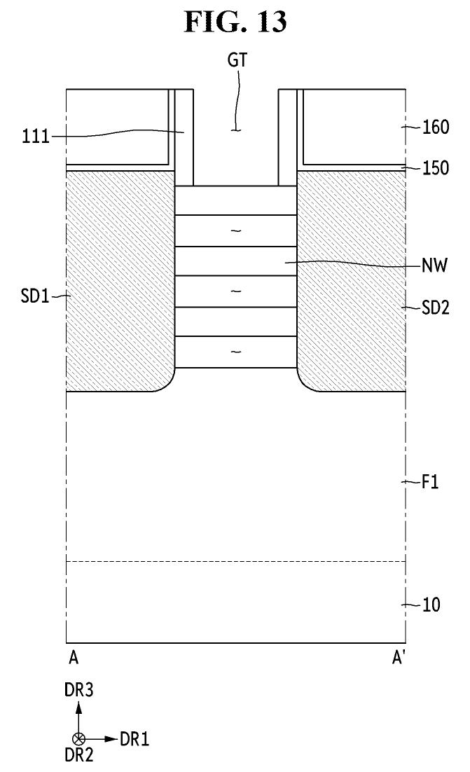

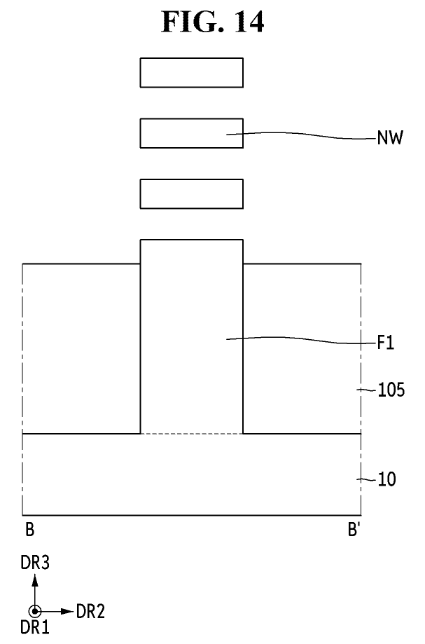

Referring to FIGS. 13 and 14, the dummy gate DG (see FIG. 11), the pad oxide 30 (see FIG. 11), and the first semiconductor layer 21 (see FIG. 11) may each be etched. The etched portions of the dummy gate DG (see FIG. 11), the pad oxide 30 (see FIG. 11), and the first semiconductor layer 21 (see FIG. 11) may be defined as the gate trench GT.

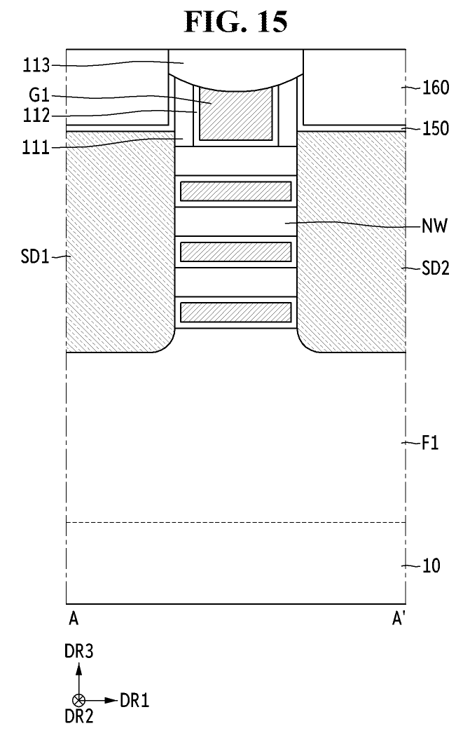

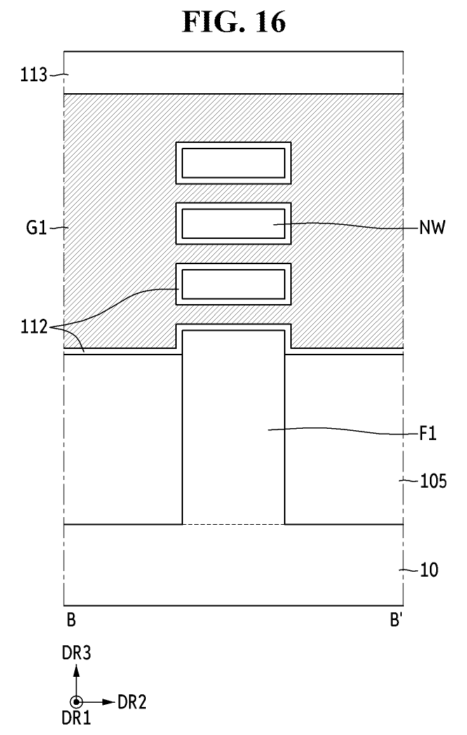

Referring to FIGS. 15 and 16, the gate insulating layer 112, the gate electrode G1, and the capping pattern 113 may be sequentially formed inside the gate trench GT (see FIG. 13).

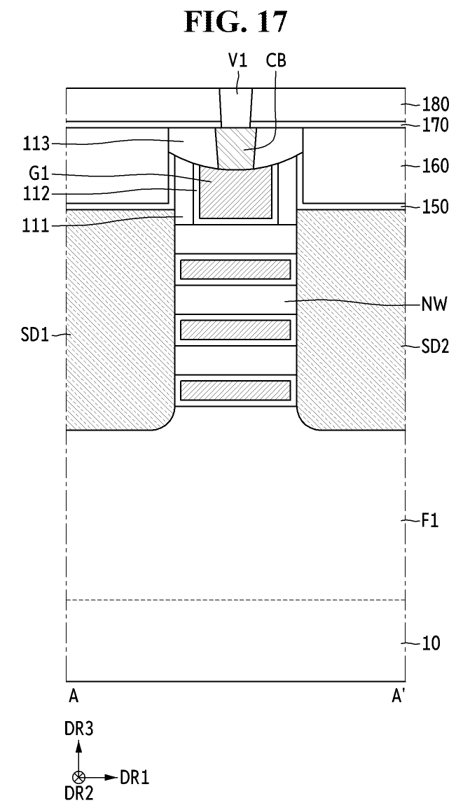

Referring to FIGS. 17 to 19, the gate contact CB may be formed to extend through the capping pattern 113 in the vertical direction DR3 and connect to the gate electrode G1. Subsequently, the second etching stop layer 170 and the second upper interlayer insulating layer 180 may be sequentially formed on the upper surface of each of the first upper interlayer insulating layer 160, the capping pattern 113, and the gate contact CB. Subsequently, the via V1 may be formed to extend through the second etching stop layer 170 and the second upper interlayer insulating layer 180 in the vertical direction DR3 to connect to the gate contact CB.

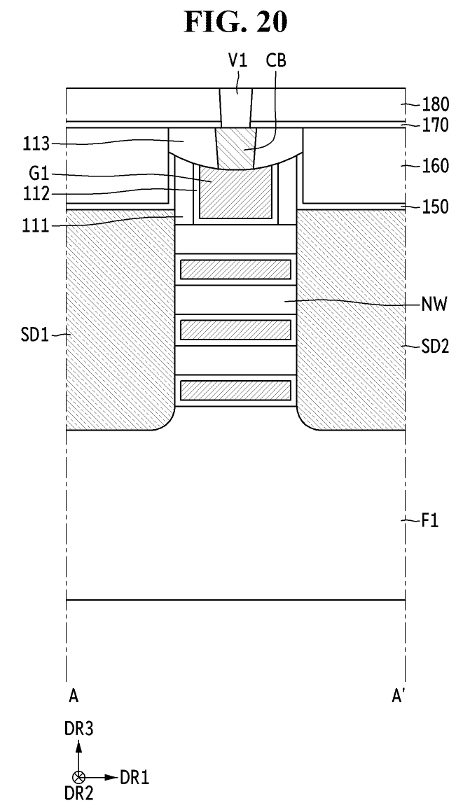

Referring to FIGS. 20 to 22, the substrate 10 (see FIGS. 17 to 19) may be etched. For example, the substrate 10 (see FIGS. 17 to 19) may be etched through a planarization process. After this etching process is completed, the bottom surface of each of the active pattern F1 and the field insulating layer 105 may be exposed.

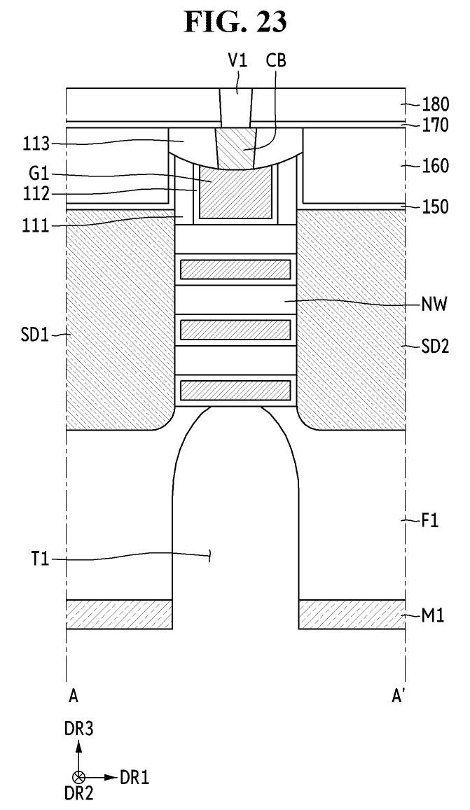

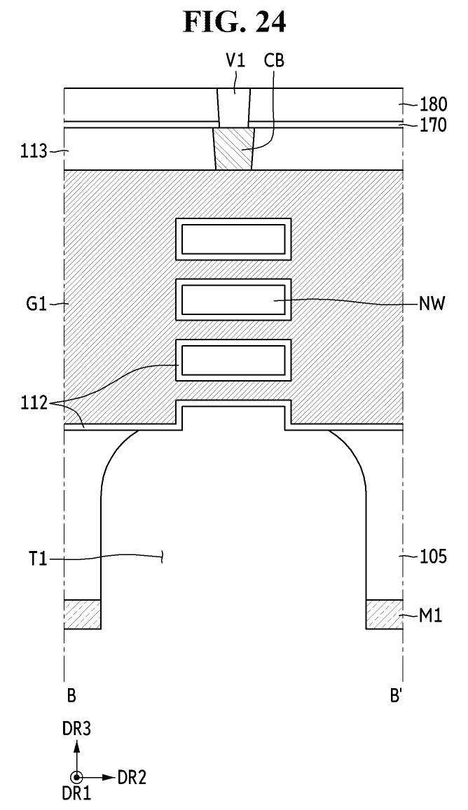

Referring to FIGS. 23 and 24, a mask pattern M1 may be formed at the bottom surface of each of the active pattern F1 and the field insulating layer 105. For example, the mask pattern M1 may expose a portion of each of the active pattern F1 and the field insulating layer 105 formed beneath the gate electrode G1. Subsequently, using the mask pattern M1 as a mask, a portion of the active pattern F1 and the field insulating layer 105 may be etched to form an isolation trench T1. For example, the gate insulating layer 112 may be exposed through the upper surface of the isolation trench T1.

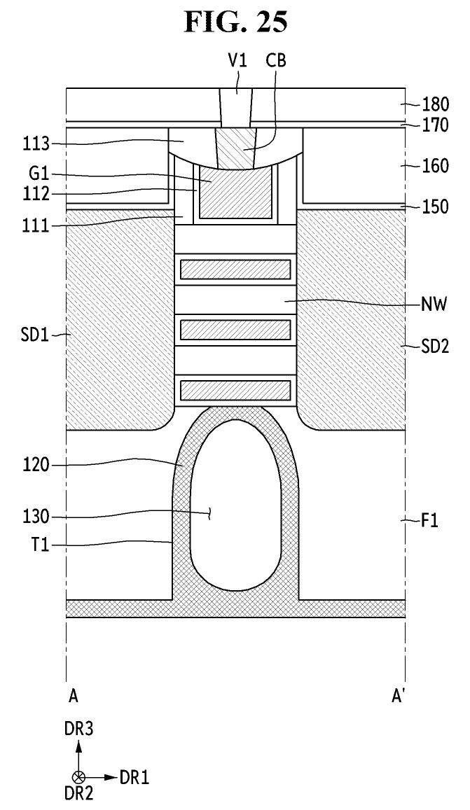

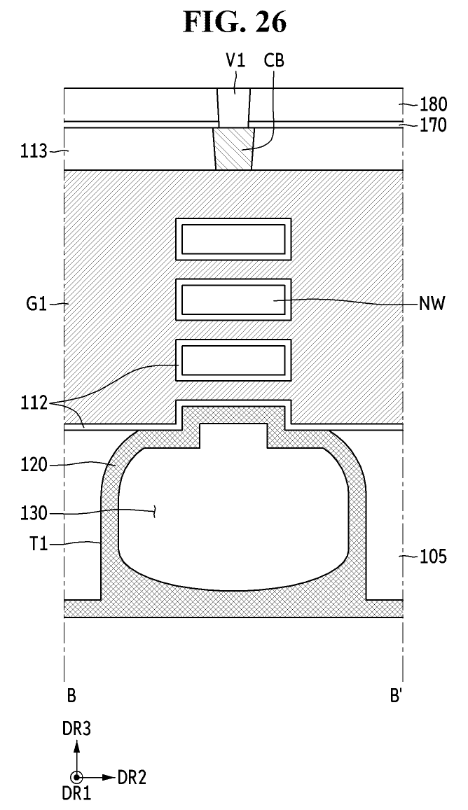

Referring to FIGS. 25 and 26, the mask pattern M1 (see FIGS. 23 and 24) may be removed. Then, the liner layer 120 may be formed at the surface of the isolation trench T1, the bottom surface of the active pattern F1, and the bottom surface of the field insulating layer 105. While the liner layer 120 is being formed, the air gap 130, which is surrounded by the liner layer 120 from the inside of the isolation trench T1, may be formed. For example, the bottom surface of the air gap 130 may be formed higher than the bottom surfaces of the active pattern F1 and the field insulating layer 105, respectively.

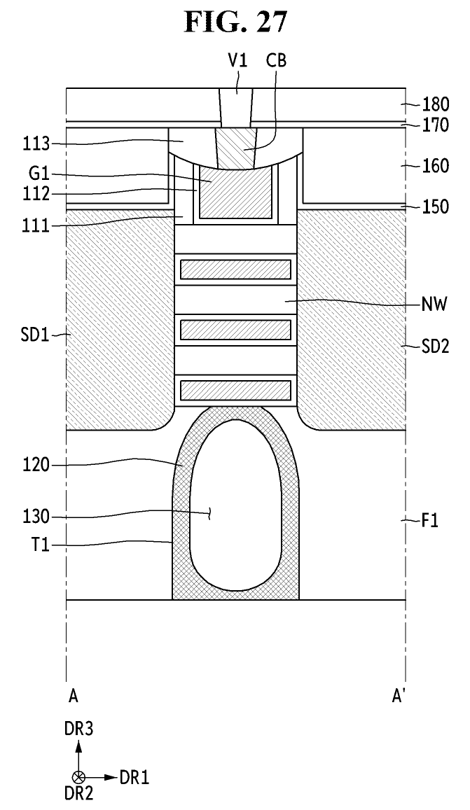

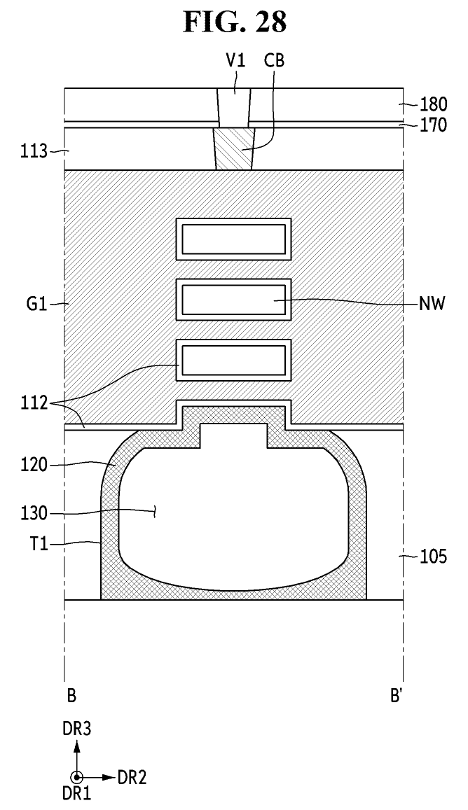

Referring to FIGS. 27 and 28, the planarization process may be performed to expose the bottom surface of each of the active pattern F1 and the field insulating layer 105. After this etching process is completed, the lowermost surface of the liner layer 120 may be formed on the same plane as each of the bottom surfaces of the active pattern F1 and the field insulating layer 105. For example, after this etching process is completed, the air gap 130 is not exposed.

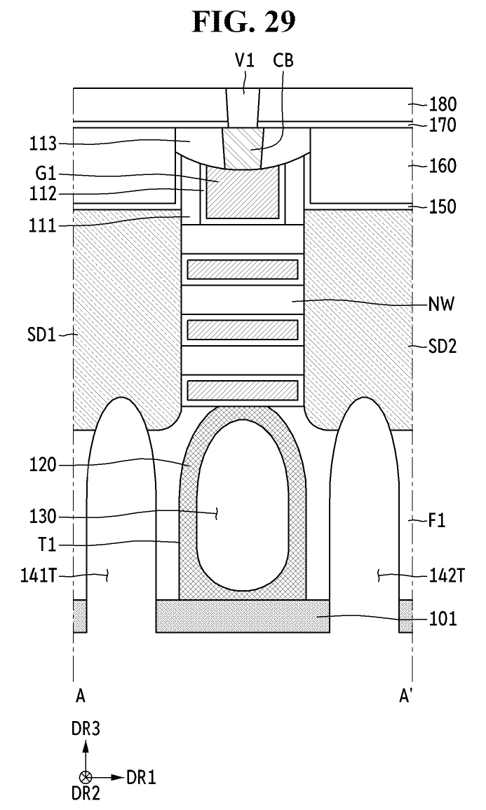

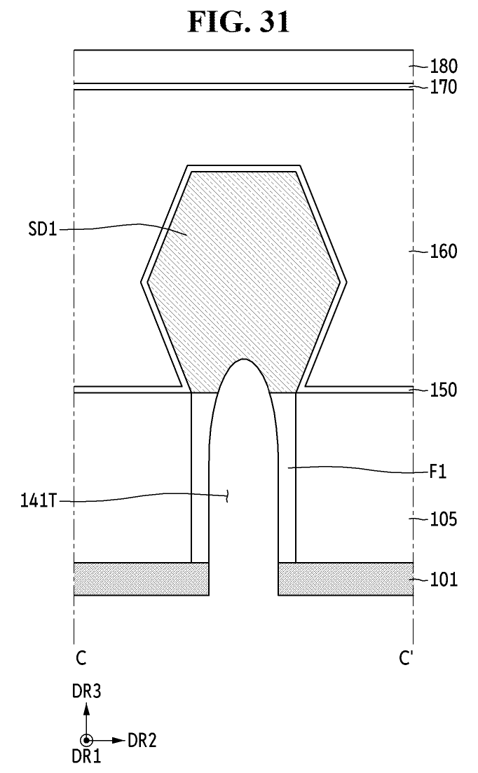

Referring to FIG. 29 and FIG. 31, the insulating pattern 101 may be formed at the bottom surface of the active pattern F1, the bottom surface of the field insulating layer 105, and the lowermost surface of the liner layer 120. For example, insulating pattern 101 may expose the bottom surface of the active pattern F1 formed beneath each of the first and second source/drain regions SD1, SD2. Subsequently, using the insulating pattern 101 as a mask, the active pattern F1 may be etched to form the first and second contact trenches 141T, 142T. The first contact trench 141T may be formed beneath the first source/drain region SD1, and the second contact trench 142T may be formed beneath the second source/drain region SD2. For example, the first contact trench 141T may extend into the inside of the first source/drain region SD1, and the second contact trench 142T may extend into the inside of the second source/drain region SD2.

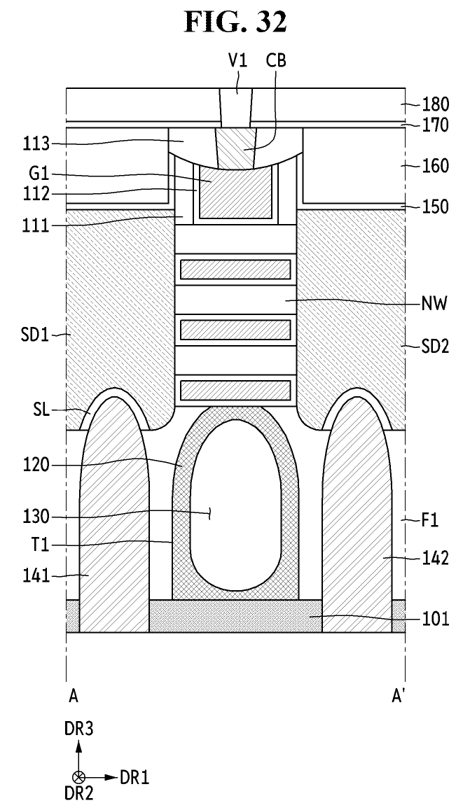

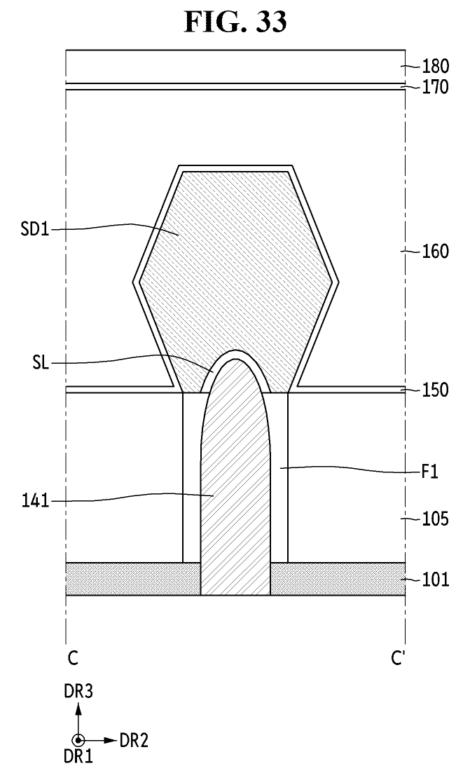

Referring to FIGS. 32 and 33, the first source/drain contact 141 may be formed inside the first contact trench 141T (see FIGS. 29 and 31), and the second source/drain contact 142 may be formed inside the second contact trench 142T (see FIG. 29). Additionally, the silicide layer SL may be formed at the interface between the first source/drain contact 141 and the first source/drain region SD1, as well as at the interface between the second source/drain contact 142 and the second source/drain region SD2.

Referring to FIG. 2 to FIG. 4, the lower interlayer insulating layer 100 may be formed at the bottom surface of the insulating pattern 101, the first and second source/drain contacts 141, 142, respectively. Through this fabrication process, the semiconductor devices shown in FIG. 2 to FIG. 4 may be fabricated.

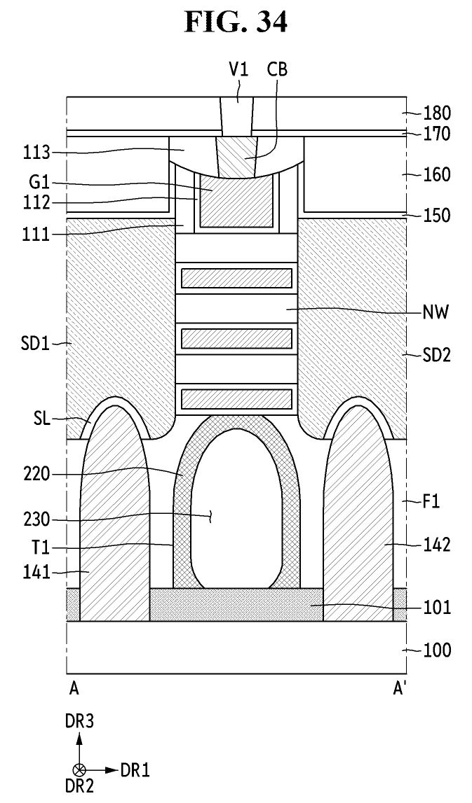

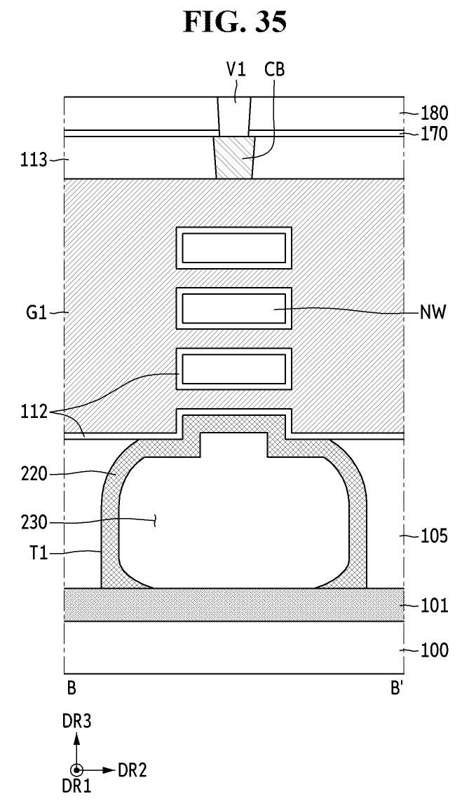

Hereinafter, a semiconductor device according to some other implementations of the present disclosure will be described with reference to FIGS. 34 and 35. The differences from the semiconductor devices shown in FIG. 1 to FIG. 4 will be described.

FIG. 34 and FIG. 35 are cross-sectional views for explaining a semiconductor device according to other implementations of the present disclosure.

Referring to FIGS. 34 and 35, in the semiconductor device according to some other implementations of the present disclosure, the bottom surface of the air gap 230 may be in contact with the upper surface of the insulating pattern 101. In other words, the bottom surface of the air gap 230 may be defined by the upper surface of the insulating pattern 101. For example, the bottom surface of the air gap 230 may be formed on the same plane as the lowermost surface of the liner layer 220.

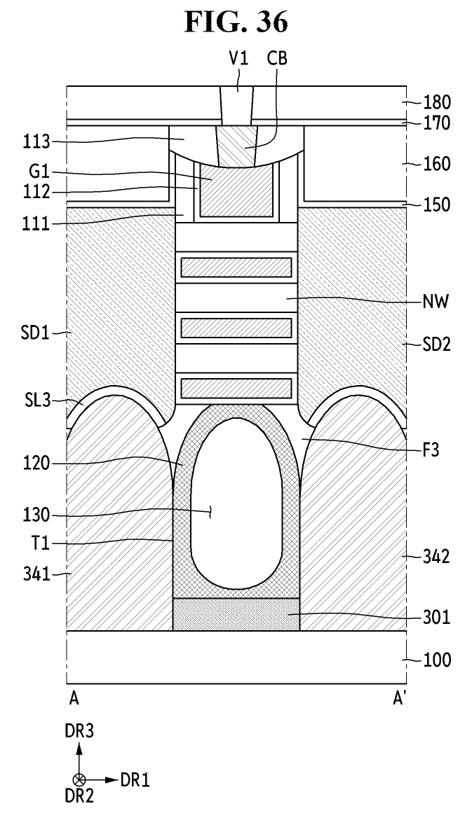

Hereinafter, a semiconductor device according to several other implementations of the present disclosure will be described with reference to FIG. 36. The differences from the semiconductor devices shown in FIGS. 1 to 4 will be described.

FIG. 36 is a cross-sectional view for explaining a semiconductor device according to several other implementations of the present disclosure.

Referring to FIG. 36, in a semiconductor device according to several other implementations of the present disclosure, each of the first and second source/drain contacts 341, 342 may be in contact with the liner layer 120.

For example, the sidewall of the first source/drain contact 341 in the first horizontal direction DR1 may be in contact with the outer sidewall of the liner layer 120 in the first horizontal direction DR1. Additionally, the sidewall of the second source/drain contact 342 in the first horizontal direction DR1 may be in contact with the outer sidewall of the liner layer 120 in the first horizontal direction DR1. For example, the active pattern F3 may be disposed between the upper portions of the first and second source/drain contacts 341, 342 and the upper outer sidewall of the liner layer 120.

For example, the sidewall of the insulating pattern 301 that is in contact with the first source/drain contact 341 and the sidewall of the liner layer 120 that is in contact with the first source/drain contact 341 may have a continuous sloped profile. Additionally, the sidewall of the insulating pattern 301 that is in contact with the second source/drain contact 342 and the sidewall of the liner layer 120 that is in contact with the second source/drain contact 342 may have a continuous sloped profile. For example, the silicide layer SL3 may be disposed along the interface between the first source/drain contact 341 and the first source/drain region SD1. In addition, the silicide layer SL3 may be disposed along the interface between the second source/drain contact 342 and the second source/drain region SD2.

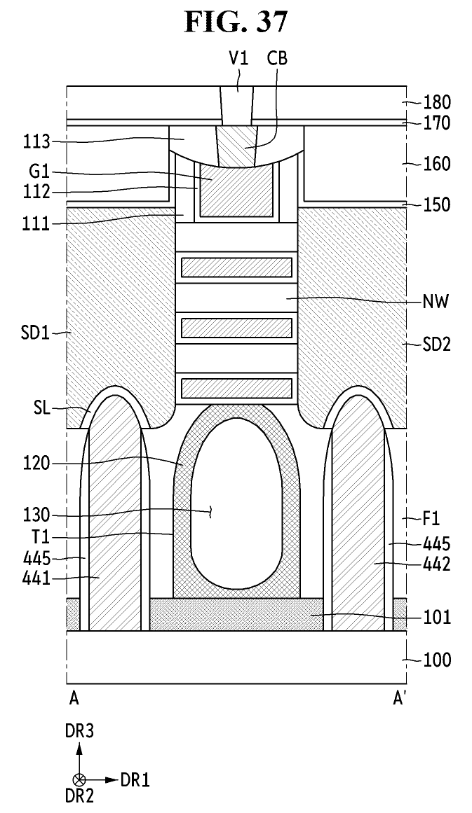

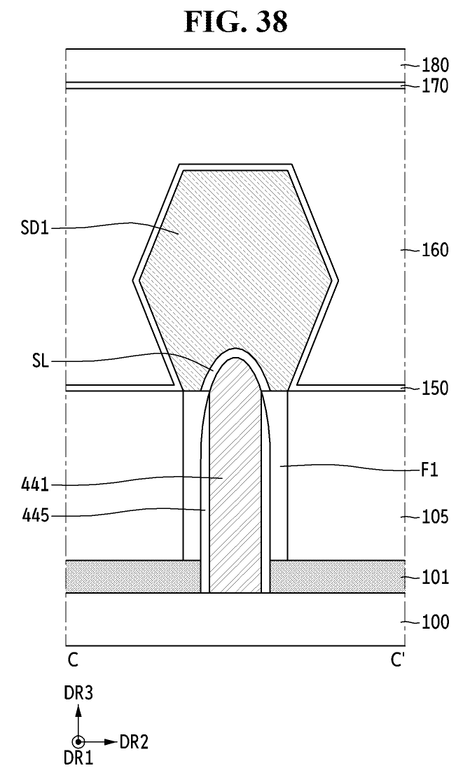

Hereinafter, a semiconductor device according to another several implementations of the present disclosure will be described with reference to FIGS. 37 and 38. The description will be focused on the differences from the semiconductor devices shown in FIG. 1 to FIG. 4.

FIGS. 37 and 38 are cross-sectional views for explaining a semiconductor device according to another several implementations of the present disclosure.

Referring to FIGS. 37 and 38, in a semiconductor device according to some other implementations of the present disclosure, a contact barrier layer 445 may be disposed on the sidewalls of the first and second source/drain contacts 441, 442.

For example, the contact barrier layer 445 may be disposed between the first source/drain contact 441 and the active pattern F1. The contact barrier layer 445 may be disposed between the first source/drain contact 441 and the insulating pattern 101. Additionally, the contact barrier layer 445 may be disposed between the second source/drain contact 442 and the active pattern 101. The contact barrier layer 445 may be disposed between the second source/drain contact 442 and the insulating pattern 101.

For example, the bottom surface of the contact barrier layer 445 may be formed on the same plane as the bottom surface of the first and second source/drain contacts 441, 442, respectively. For example, the bottom surface of the contact barrier layer 445 may be in contact with the upper surface of the lower interlayer insulating layer 100. The contact barrier layer 445 may include an insulating material. The contact barrier layer 445 may include at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), or combinations thereof. However, the present disclosure is not limited thereto.

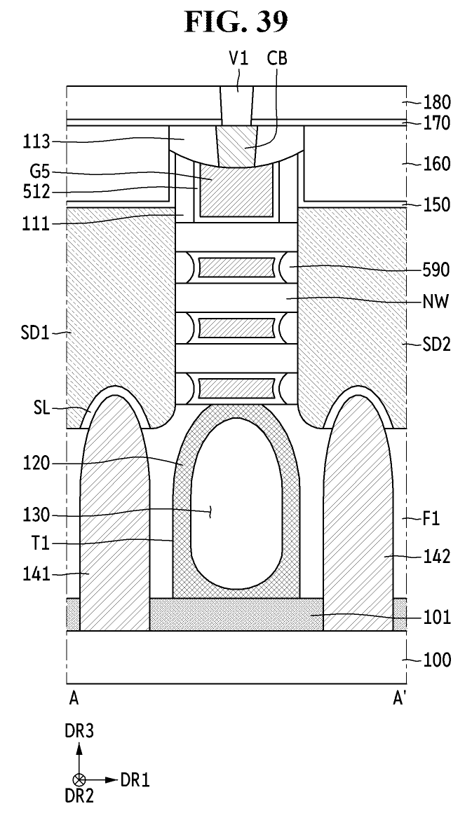

Hereinafter, a semiconductor device according to several other implementations of the present disclosure will be described with reference to FIG. 39. The differences from the semiconductor device shown in FIGS. 1 to 4 will be described.

FIG. 39 is a cross-sectional view for explaining the semiconductor device according to several other implementations of the present disclosure.

Referring to FIG. 39, in the semiconductor device according to several other implementations of the present disclosure, an inner spacer 590 may be disposed between each of the first and second source/drain regions SD1, SD2 and the gate electrode G5.

For example, the inner spacer 590 may be disposed on both sidewalls of the gate electrode G5 in the first horizontal direction DR1, between the upper surface of the active pattern F1 and the bottom surface of the lowermost nanosheet of the plurality of nanosheets NW. Additionally, the inner spacer 590 may be disposed on both sidewalls of the gate electrode G5 in the first horizontal direction DR1, between adjacent plurality of nanosheets NW. The inner spacer 590 may be in contact with the plurality of nanosheets NW, the first and second source/drain regions SD1, SD2, and the gate insulating layer 512, respectively. For example, the inner spacer 590 may include at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), or combinations thereof.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although the implementations of the present disclosure have been described above with reference to the accompanying drawings, it will be understood that the present disclosure is not limited to these implementations and may be implemented in various other forms. Those skilled in the art to which the present disclosure pertains will recognize that it can be implemented in other specific forms without departing from its technical concept or essential features. Accordingly, the above-described implementations should be understood as illustrative rather than restrictive in all respects.

What is claimed is:

1. A semiconductor device comprising:
an active pattern extending in a first horizontal direction;
a plurality of nanosheets stacked and spaced apart from each other in a vertical direction on the active pattern;
a gate electrode extending in a second horizontal direction different from the first horizontal direction on the active pattern, the gate electrode surrounding the plurality of nanosheets;
a source/drain region on a first side of the gate electrode on the active pattern;
a source/drain contact beneath the source/drain region, the source/drain contact extending through the active pattern in the vertical direction, the source/drain contact electrically connected to the source/drain region;
an isolation trench beneath the plurality of nanosheets, the isolation trench extending through the active pattern in the vertical direction;
an air gap inside the isolation trench, the air gap overlapping with the gate electrode in the vertical direction; and
a liner layer along a sidewall and an upper surface of the isolation trench, wherein at least a portion of the liner layer is between the air gap and the gate electrode.

2. The semiconductor device of claim 1, comprising:
an insulating pattern beneath the isolation trench, the insulating pattern being in contact with a lowermost surface of the liner layer and a bottom surface of the active pattern, the insulating pattern surrounding at least a portion of a sidewall of the source/drain contact.

3. The semiconductor device of claim 2, wherein a bottom surface of the insulating pattern is on a same plane as a bottom surface of the source/drain contact.

4. The semiconductor device of claim 2, wherein the air gap is spaced apart from an upper surface of the insulating pattern in the vertical direction.

5. The semiconductor device of claim 2, wherein the air gap is in contact with the upper surface of the insulating pattern.

6. The semiconductor device of claim 1, wherein a width of the air gap in the second horizontal direction is greater than a width of the source/drain contact in the second horizontal direction.

7. The semiconductor device of claim 1, wherein a width of the air gap in the second horizontal direction is greater than a width of the active pattern in the second horizontal direction.

8. The semiconductor device of claim 1, wherein at least a portion of the active pattern is between the source/drain contact and the liner layer.

9. The semiconductor device of claim 1, comprising:
a gate insulating layer between the gate electrode and the plurality of nanosheets and between the gate electrode and the liner layer,
wherein an uppermost surface of the liner layer is in contact with the gate insulating layer.

10. The semiconductor device of claim 1, wherein the liner layer is spaced apart from the source/drain contact in the first horizontal direction.

11. The semiconductor device of claim 1, wherein a sidewall of the source/drain contact in the first horizontal direction is in contact with the liner layer.

12. The semiconductor device of claim 1, comprising:
an inner spacer on both sidewalls of the gate electrode in the first horizontal direction between adjacent nanosheets of the plurality of nanosheets, the inner spacer being in contact with the source/drain region.

13. A semiconductor device comprising:
an active pattern extending in a first horizontal direction;
a gate electrode extending in a second horizontal direction that is different from the first horizontal direction on the active pattern;
a first source/drain region on a first side of the gate electrode, wherein the first source/drain region is on the active pattern;
a second source/drain region on a second side of the gate electrode, opposite to the first side of the gate electrode in the first horizontal direction, wherein the second source/drain region is on the active pattern;
a first source/drain contact beneath the first source/drain region, the first source/drain contact extending through the active pattern in a vertical direction, the first source/drain contact electrically connected to the first source/drain region;
a second source/drain contact beneath the second source/drain region, the second source/drain contact extending through the active pattern in the vertical direction, the second source/drain contact electrically connected to the second source/drain region; and
an air gap between the first and second source/drain contacts, the air gap overlapping with the gate electrode in the vertical direction,
wherein a width of the air gap in the second horizontal direction is greater than a width of the first source/drain contact in the second horizontal direction.

14. The semiconductor device of claim 13, comprising:
a liner layer surrounding a surface of the air gap, wherein at least a portion of the liner layer is between the air gap and the gate electrode.

15. The semiconductor device of claim 14, wherein a lowermost surface of the liner layer is higher than a bottom surface of the first source/drain contact.

16. The semiconductor device of claim 14, wherein the liner layer is spaced apart from each of the first and second source/drain contacts in the first horizontal direction.

17. The semiconductor device of claim 13, comprising:
an insulating pattern beneath the air gap, wherein the insulating pattern is in contact with a bottom surface of the active pattern, and the insulating pattern surrounds at least a portion of sidewalls of the first and second source/drain contacts.

18. The semiconductor device of claim 17, wherein the air gap is spaced apart from an upper surface of the insulating pattern in the vertical direction.

19. The semiconductor device of claim 13, comprising:
a contact barrier layer between the active pattern and the first source/drain contact, the contact barrier layer between the active pattern and the second source/drain contact.

20. A semiconductor device comprising:
an insulating pattern;
an active pattern extending in a first horizontal direction on an upper surface of the insulating pattern, the active pattern including silicon;
a plurality of nanosheets stacked and spaced apart from each other in a vertical direction on the active pattern;
a gate electrode extending in a second horizontal direction different from the first horizontal direction on the active pattern, the gate electrode surrounding the plurality of nanosheets;
a first source/drain region on a first side of the gate electrode on the active pattern;
a second source/drain region on a second side of the gate electrode, opposite to the first side of the gate electrode in the first horizontal direction, on the active pattern;
a first source/drain contact beneath the first source/drain region, the first source/drain contact extending through the insulating pattern and the active pattern in the vertical direction, the first source/drain contact electrically connected to the first source/drain region;
a second source/drain contact beneath the second source/drain region, the second source/drain contact extending through the insulating pattern and the active pattern in the vertical direction, the second source/drain contact electrically connected to the second source/drain region;
an isolation trench beneath the plurality of nanosheets, the isolation trench extending through the active pattern in the vertical direction;
an air gap inside the isolation trench and overlapping with the gate electrode in the vertical direction; and
a liner layer along sidewalls and an upper surface of the isolation trench, the liner layer spaced apart from each of the first and second source/drain contacts in the first horizontal direction, at least a portion of the liner layer between the air gap and the gate electrode,
wherein at least a portion of the active pattern is between the liner layer and each of the first and second source/drain contacts, and
wherein a width of the air gap in the second horizontal direction is greater than a width of the first source/drain contact in the second horizontal direction.
